(19) United States
(12) Patent Application Publication
(10) Pub. No.: US 2026/0143702 A1
(43) Pub. Date: May 21, 2026

(54) THREE-DIMENSIONAL MEMORY DEVICES AND METHODS FOR FORMING THE SAME

(71) Applicant: YANGTZE MEMORY TECHNOLOGIES CO., LTD., Wuhan (CN)

(72) Inventors: Zengpeng Zhang, Wuhan (CN); Tingting Zhao, Wuhan (CN); Chao Yan, Wuhan (CN); Jianlan Wei, Wuhan (CN); Jiankang Du, Wuhan (CN); Sizhe Li, Wuhan (CN)

(21) Appl. No.: 18/955,579

(22) Filed: Nov. 21, 2024

(30) Foreign Application Priority Data
Nov. 15, 2024 (CN) 202411639600.2

(51) Int. Cl. H10B 43/27

(52) U.S. Cl. CPC H10B 43/27

(57) ABSTRACT

In certain aspects, a memory device includes a stack structure and contact structures. The stack structure includes alternating first layers and first dielectric layers. The contact structure extends into the stack structure in a first direction, and includes a first contact member extending in the first direction, a second contact member connecting to a first end of the first contact member and extending in a second direction intersected with the first direction, and a third contact member extending in the second direction and connecting to the first contact member. The third contact member is located between the first end and a second end of the first contact member.

### CROSS-REFERENCE TO RELATED APPLICATIONS

This application claims the benefit of priority to Chinese Application No. 202411639600.2, filed on Nov. 15, 2024, which is hereby incorporated by reference in its entirety.

### BACKGROUND

The present disclosure relates to three-dimensional (3D) memory devices and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A 3D memory architecture can address the density limitation in planar memory cells. The 3D memory architecture includes a memory array and peripheral devices for controlling signals to and from the memory array.

### SUMMARY

In one aspect, a memory device includes a stack structure and a contact structure. The stack structure includes alternating first layers and first dielectric layers. The contact structure extends into the stack structure in a first direction, and includes a first contact member extending in the first direction, a second contact member connecting to a first end of the first contact member and extending in a second direction intersected with the first direction, and a third contact member extending in the second direction and connecting to the first contact member. The third contact member is located between the first end and a second end of the first contact member.

In some implementations, the first layers in a first portion of the stack structure include second dielectric layers, the contact structure extends into the first portion of the stack structure, and the third contact member and the second contact member are spaced apart by one or more layers from the first and second dielectric layers in the first direction.

In some implementations, the contact structure further includes: a first outer metal layer extending in the first direction and surrounding the first contact member; and a second outer metal layer extending in the second direction, connecting to a first end of the first outer metal layer, and covering an outer surface of the second contact member. The third contact member connects to the first outer metal layer between the first end and a second end of the first outer metal layer.

In some implementations, the first outer metal layer includes a first outer segment and a second outer segment; the first outer segment is located on a first side of the third contact member that is away from the second contact member; the second outer segment is located on a second side of the third contact member that is close to the second contact member and opposite to the first side; and the contact structure further includes a contact spacer extending in the first direction and surrounding the first outer segment.

In some implementations, the contact structure further includes: a first inner metal layer extending in the first direction and surrounded by the first contact member; and a second inner metal layer extending in the second direction, connecting to an end of the first inner metal layer, and covering an inner surface of the second contact member.

In some implementations, the first contact member includes a first contact segment, a contact shoulder, and a second contact segment. The contact shoulder connects to the first contact segment and the second contact segment. The first contact segment is located on a first side of the third contact member that is away from the second contact member, and the second contact segment connects to the second contact member and is located on a second side of the third contact member that is opposite to the first side.

In some implementations, in a second direction perpendicular to the first direction, a size of an end of the first contact segment that connects to the contact shoulder is greater than a size of an end of the second contact segment that also connects to the contact shoulder.

In some implementations, the first layers in a second portion adjacent to the first portion of the stack structure include conductive layers. The third contact member is in a same layer as one of the conductive layers and connects to the one of the conductive layers.

In another aspect, a memory device includes a stack structure and a contact structure. The stack structure includes alternating first layers and first dielectric layers. The contact structure extends into the stack structure in a first direction, and includes a first contact member extending in the first direction, a second contact member connecting to an end of the first contact member and extending in a second direction intersected with the first direction, and a third contact member extending in the second direction and connecting to the second contact member. A first thickness of the second contact member in the first direction is greater than a second thickness of the first contact member in the second direction.

In some implementations, the second thickness of the first contact member is a maximal thickness of the first contact member in the second direction.

In some implementations, the first layers in a first portion of the stack structure include second dielectric layers. The contact structure extends into the first portion of the stack structure. The first thickness of the second contact member is equal to or greater than a thickness of two or more layers from the first dielectric layers and the second dielectric layers in the first direction.

In some implementations, the contact structure further includes an outer metal layer extending in the first direction and surrounding the first contact member.

In some implementations, the contact structure further includes a contact spacer extending in the first direction and surrounding the outer metal layer.

In some implementations, the contact structure further includes: a first inner metal layer extending in the first direction and surrounded by the first contact member; and a second inner metal layer extending in the second direction, connecting to an end of the first inner metal layer, and covering an inner surface of the second contact member.

In some implementations, the first layers in a second portion adjacent to the first portion of the stack structure include conductive layers; and the third contact member is in a same layer as one of conductive layers and connects to the one of the conductive layers.

In still another aspect, a method for forming a memory device is disclosed. The method includes forming a stack structure including alternating first dielectric layers and second dielectric layers. The method also includes forming a contact structure extending into the stack structure in a first direction. The contact structure includes: a first contact member extending in the first direction; a second contact member connecting to a first end of the first contact member and extending in a second direction intersected with the first direction; and a third contact member extending in the second direction and connecting to the first contact member. The third contact member is located between the first end and a second end of the first contact member.

In some implementations, forming the contact structure includes: forming a contact hole extending into the stack structure in the first direction; and forming the contact structure in the contact hole.

In some implementations, forming the contact hole includes: forming a first opening extending into the stack structure in the first direction; forming a lateral opening below a bottom of the first opening; and forming a second opening below a bottom of the lateral opening, where the second opening extends further into the stack structure from the bottom of the lateral opening in the first direction.

In some implementations, forming the contact structure further includes: forming the third contact member in the lateral opening; forming a first outer metal layer on a sidewall of the contact hole; and forming a second outer metal layer on a bottom of the second opening. The second outer metal layer connects to a first end of the first outer metal layer. The third contact member connects to the first outer metal layer between the first end and a second end of the first outer metal layer.

In some implementations, forming the contact structure further includes: forming the second contact member on the second outer metal layer; and forming the first contact member on a sidewall of the first outer metal layer.

In some implementations, forming the contact structure further includes forming a contact spacer on a sidewall of the first opening before the lateral opening is formed below the bottom of the first opening. Forming the first outer metal layer on the sidewall of the contact hole includes: forming a first outer segment of the first outer metal layer on a sidewall of the contact spacer, where the first outer segment is located on a first side of the third contact member that is away from the second contact member; and forming a second outer segment of the first outer metal layer on a sidewall of the second opening, where the second outer segment is located on a second side of the third contact member that is close to the second contact member and opposite to the first side.

In some implementations, a sidewall shoulder is formed in a region where the lateral opening meets the second opening. Forming the first outer metal layer on the sidewall of the contact hole further includes forming an outer metal shoulder of the first outer metal layer on the sidewall shoulder, where the outer metal shoulder connects to the third contact member. Forming the first contact member on the sidewall of the first outer metal layer includes forming a first contact segment on a sidewall of the first outer segment, a contact shoulder on the outer metal shoulder, and a second contact segment on a sidewall of the second outer segment. The contact shoulder connects to the first contact segment and the second contact segment, and the contact shoulder also connects to the outer metal shoulder.

In some implementations, in a second direction perpendicular to the first direction, a size of an end of the first contact segment that connects to the contact shoulder is greater than a size of an end of the second contact segment that also connects to the contact shoulder.

In some implementations, forming the contact structure further includes: forming a first inner metal layer on a sidewall of the first contact member; and forming a second inner metal layer on the second contact member. The second inner metal layer connects to an end of the first inner metal layer.

In some implementations, the stack structure includes a first portion and a second portion adjacent to the first portion, and the contact structure extends in the first portion of the stack structure. The method further includes performing a gate line replacement process to replace parts of the second dielectric layers in the second portion of the stack structure with conductive layers.

In some implementations, the third contact member is in a same layer as one of conductive layers and connects to the one of the conductive layers.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a plan view of a 3D memory device having contact structures, according to some aspects of the present disclosure.

FIG. 2A illustrates a cross-sectional side view of a part of a 3D memory device having contact structures, according to some examples of the present disclosure.

FIG. 2B illustrates an enlarged view of a contact structure, according to some examples of the present disclosure.

FIG. 3A illustrates cross-sectional side views of a 3D memory device having contact structures with a first structure design, according to some aspects of the present disclosure.

FIG. 3B illustrates cross-sectional side views of a 3D memory device having contact structures with a second structure design, according to some aspects of the present disclosure.

FIGS. 4A-4B illustrate a cross-sectional side view of a contact structure with the first structure design, according to some aspects of the present disclosure.

FIGS. 4C-4H illustrate cross-sectional side views of contact structures with the second structure design, according to some aspects of the present disclosure.

FIGS. 5A-5K illustrate a fabrication process for forming a 3D memory device having contact structures, according to some aspects of the present disclosure.

FIG. 6 is a flowchart of a method for forming a 3D memory device having contact structures, according to some aspects of the present disclosure.

FIGS. 7A-7F illustrate a fabrication process for forming contact structures in a stack structure, according to some aspects of the present disclosure.

FIGS. 8A-8C illustrate another fabrication process for forming contact structures in a stack structure, according to some aspects of the present disclosure.

FIGS. 9A-9F illustrate still another fabrication process for forming contact structures in a stack structure, according to some aspects of the present disclosure.

FIG. 10 is a flowchart of another method for forming a 3D memory device having contact structures, according to some aspects of the present disclosure.

FIG. 11 illustrates a block diagram of an exemplary system having a 3D memory device, according to some aspects of the present disclosure.

FIG. 12A illustrates a diagram of an exemplary memory card having a 3D memory device, according to some aspects of the present disclosure.

FIG. 12B illustrates a diagram of an exemplary solid-state drive (SSD) having a 3D memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which lateral contact members and/or vertical contacts are formed) and one or more dielectric layers.

In some 3D memory devices, such as 3D NAND memory devices, memory cells for storing data are vertically stacked through a stack structure (e.g., a memory stack) in vertical channel structures. 3D memory devices usually include staircase structures formed on one or more sides (edges), or at the center, of the stacked storage structure for purposes such as word line pick-up/fan-out using contacts landed onto different steps/levels of a staircase structure. In some implementations, the word line pick-up/fan-out functions can be achieved without using the staircase structures and the contacts, so that the manufacturing cost can be reduced and the fabrication process can be simplified. For example, the two structures—staircase structure and contact, as well as their separate processes, can be merged into a single contact structure (e.g., a word line pick-up structure) in one process, thereby reducing the manufacturing cost and simplifying the process.

Specifically, contact structures can be formed to extend through alternating first dielectric layers and second dielectric layers in a stack structure of a memory device. The word line pick-up/fan-out functions of the memory device can be achieved by the contact structures which connect to gate lines of the memory device, respectively. The gate lines in the memory device are formed by replacing parts of the second dielectric layers in the stack structure with conductive layers such as tungsten (W) layers. The W layers are surrounded by high dielectric constant (high-k) gate dielectric layers (e.g., aluminum oxide (AlO)), and adjacent W layers are separated by the first dielectric layers (e.g., silicon oxide). In some examples, tungsten hexafluoride (WF6) may be used to deposit the W layers into the stack structure to replace the parts of the second dielectric layers, respectively. As a result, the W layers formed thereof usually include Fluoride ions (F−). In a subsequent thermal process, these Fluoride ions (F−) may be diffused and replace the O bonds (—O) in silicon oxide and AlO to form Si—F bonds and Al—F bonds, respectively (e.g., the Si—O bonds in silicon oxide and Al—O bonds in AlO are changed to Si—F bonds and Al—F bonds, respectively). Because the energy of Si—F bonds and the energy of Al—F bonds are lower than the energy of Si—O bonds and Al—O bonds, respectively, the structure of silicon oxide (e.g., the first dielectric layers) and the structure of AlO (e.g., the high-k gate dielectric layers) become instable. When a large volume of free H ions (H+) are provided in an environment of the thermal process, the F ions (F−) may be combined with the H ions (H+), causing damages to the structure of silicon oxide and the structure of AlO. Then, the anti-breakdown ability of the structure of silicon oxide is degraded, which may result in an occurrence of leakage between the gate lines (e.g., the W layers).

For example, during a thermal process, a slight creak or bubble may appear in a connection interface where a contact structure connects to a respective gate line (e.g., a respective W layer), due to the stress changes on the material filled in the contact structure. Meanwhile, the contact structure may be squeezed by the gate line and array common source (ACS) poly, resulting in a structural instability of the contact structure and the gate line. In the thermal process, the hot temperature may provide power for the F ions (F−) to diffuse, and a H+ rich environment in the thermal process will cause the F− to be combined with H+. As a result, the structure of silicon oxide (e.g., the first dielectric layers) and the structure of AlO (e.g., the high-k gate dielectric layers) can be damaged, causing leakage between the gate lines (the W layers). A severe yield loss may occur.

To address one or more of the aforementioned issues, the present disclosure introduces a solution that can improve the connection stability between contact structures and gate lines in a memory device to reduce or eliminate leakages between the gate lines. In a first example, a contact structure disclosed herein may include a first contact member (e.g., a vertical contact member) extending in a vertical direction, a second contact member (e.g., a bottom contact member) connecting to an end of the first contact member and extending in a lateral direction, and a third contact member (e.g., a lateral contact member) extending in the lateral direction and connecting to the second contact member. By increasing the thickness of the second contact member (e.g., the bottom contact member) in the vertical direction, the stability of the contact structure can be increased, and the stability of a connection between the contact structure and a gate line coupled to the contact structure is also improved.

In a second example, a contact structure disclosed herein may include a first contact member (e.g., a vertical contact member) extending in the vertical direction, a second contact member (e.g., a bottom contact member) connecting to a first end of the first contact member and extending in the lateral direction, and a third contact member (e.g., a lateral contact member) extending in the lateral direction and connecting to the first contact member. By configuring the third contact member to be located between the first end and a second end of the first contact member, the stability of the connection between the contact structure and a gate line coupled with the contact structure is improved.

In either example described above, during a thermal process, the improvement on the connection stability between the contact structure and the gate line can reduce or eliminate the occurrence of any creak or bubble in the connection interface where the contact structure meets the gate line. As a result, the leakages between the gate lines can be reduced or eliminated to avoid yield loss. Besides, the manufacturing process of the contact structure disclosed herein is simplified, and the manufacturing cost of the memory device can be reduced.

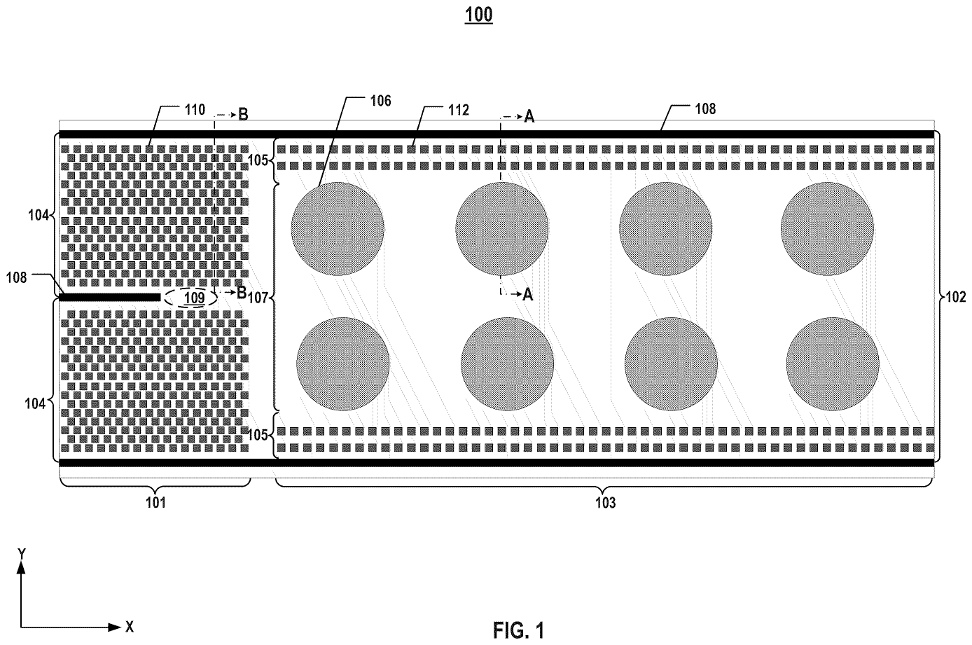

FIG. 1 illustrates a plan view of a 3D memory device 100 having contact structures 106, according to some aspects of the present disclosure. In some implementations, 3D memory device 100 is a NAND Flash memory device in which memory cells are provided in the form of an array of NAND memory strings. It is noted that x and y axes are included in FIG. 1 to illustrate two orthogonal (perpendicular) directions in the wafer plane. The x-direction is the word line direction of 3D memory device 100, and the y-direction is the bit line direction of 3D memory device 100.

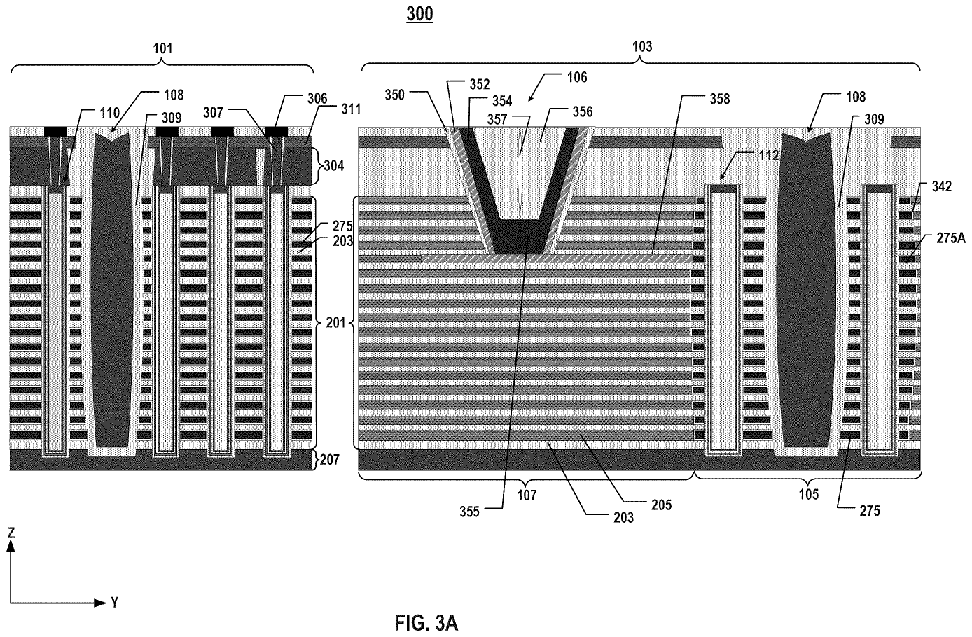

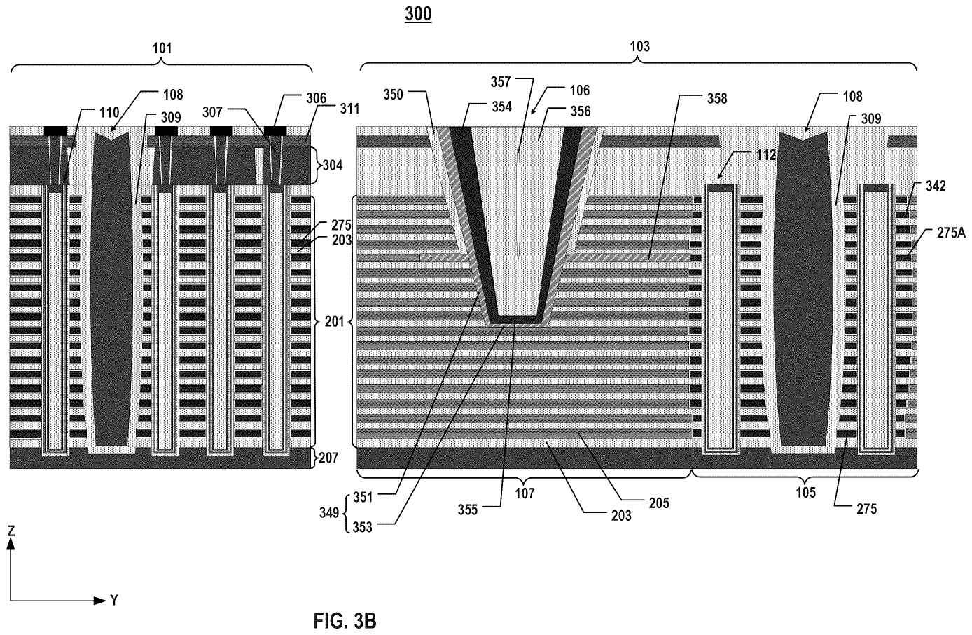

As shown in FIGS. 1, 3D memory device 100 can include one or more blocks 102 arranged in the y-direction (the bit line direction) separated by parallel slit structures 108, such as gate line slits (GLSs). In some implementations in which 3D memory device 100 is a NAND Flash memory device, each block 102 is the smallest erasable unit of the NAND Flash memory device. Each block 102 can further include multiple fingers 104 in the y-direction separated by some slit structures 108 with “H” cuts 109.

As shown in FIGS. 1, 3D memory device 100 can be divided into at least a core array region 101 in which an array of channel structures 110 are formed, as well as a connection region 103 in which contact structures 106 are formed. Core array region 101 and connection region 103 are arranged in the x-direction (the word line direction), according to some implementations. It is understood that although one core array region 101 and one connection region 103 are illustrated in FIG. 1, multiple core array regions 101 and/or multiple connection regions 103 may be included in 3D memory device 100, for example, one connection region 103 between two core array regions 101 in the x-direction, in other examples. It is also understood that FIG. 1 only illustrates portions of core array region 101 that are adjacent to connection region 103.

As described below in more detail, connection region 103 can include conductive portions 105 and dielectric portions 107 arranged in the y-direction. As shown in FIG. 1, contact structures 106 are disposed in dielectric portion 107, while dummy channel structures 112 are disposed in conductive portion 105 of connection region 103 to provide mechanical support and/or load balancing, according to some implementations. In some implementations, dummy channel structures 112 can also be disposed in dielectric portion 107 of connection region 103 as well, for example, between contact structures 106 in the x-direction. In some implementations, dummy channel structures 112 are not disposed in dielectric portion 107 of connection region 103, i.e., only in conductive portion 105 of connection region 103. As shown in FIG. 1, each finger 104 of 3D memory device 100 can include one row of contact structures 106 disposed in dielectric portion 107 of connection region 103. It is understood that the layout and arrangement of contact structures 106, as well as the shape of each contact structure 106, may vary in different examples.

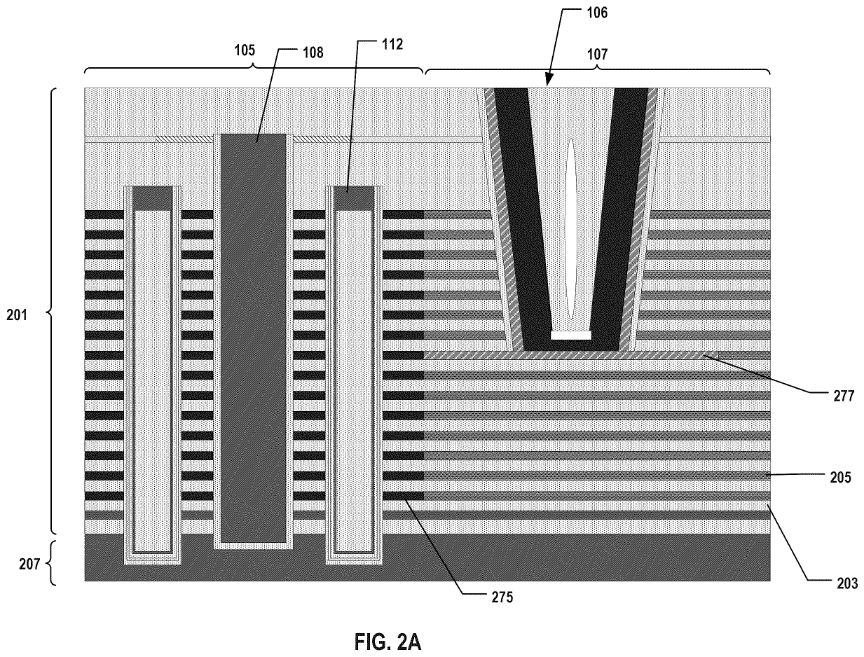

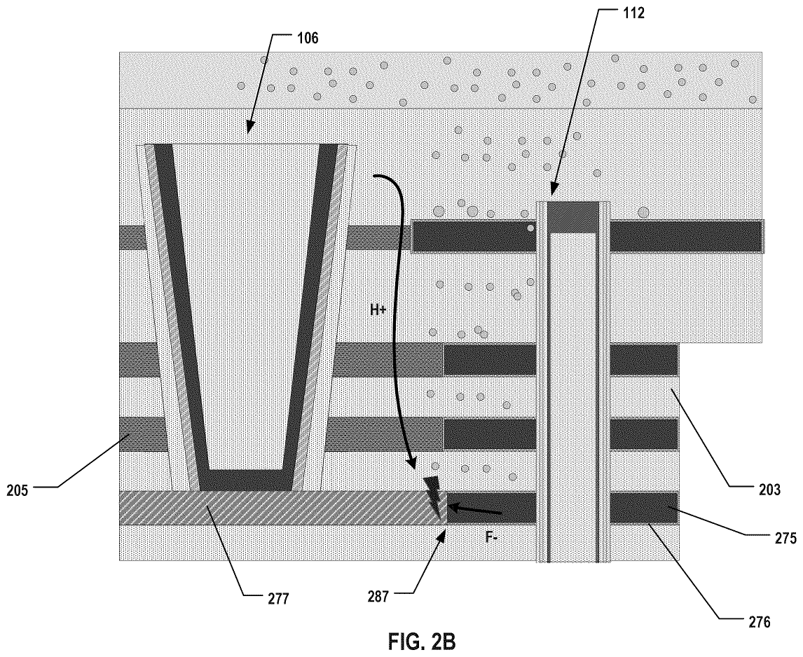

FIG. 2A illustrates a cross-sectional side view of a part of a 3D memory device 200 having contact structures 106, according to some examples of the present disclosure. Memory device 200 can be an example of memory device 100 of FIG. 1. The cross-section may be along the AA direction in connection region 103 of FIG. 1. Memory device 200 may include a stack structure 201, which may include a first portion and a second portion adjacent to the first portion. The first portion of stack structure 201 may include a part of stack structure 201 in dielectric portion 107 of connection region 103 shown in FIG. 1. The second portion of stack structure 201 may include another part of stack structure 201 in (i) conductive portion 105 of connection region 103 and (ii) core array region 101 shown in FIG. 1. Stack structure 201 may include alternating first layers and first dielectric layers 203.

Stack structure 201 can include vertically interleaved first layers and first dielectric layers 203. First layers and first dielectric layers 203 can alternate in the vertical direction (the z-direction). In some implementations, stack structure 201 can include a plurality of material layer pairs stacked vertically in the z-direction, each of which includes a first layer and a first dielectric layer 203. The number of the material layer pairs in stack structure 201 can determine the number of memory cells in memory device 100.

The first layers in the first portion of stack structure 201 may include second dielectric layers 205. That is, the first portion of stack structure 201 may include alternating first dielectric layers 203 and second dielectric layers 205, as shown in FIG. 2A. The first layers in the second portion of stack structure 201 may include conductive layers 275. That is, the second portion of stack structure 201 may include alternating first dielectric layers 203 and conductive layers 275, as shown in FIG. 2A.

In some implementations, memory device 200 is a NAND Flash memory device, and stack structure 201 is a stacked storage structure through which NAND memory strings are formed. In some implementations, each conductive layer in the second portion of stack structure 201 functions as a gate line of the NAND memory strings (in the forms of channel structures 110) in core array region 101, ending in conductive portion 105 of connection region 103 for word line pick-up/fan-out through contact structures 106. The gate lines (i.e., the conductive layers) at different depths/level of the second portion of stack structure 201 each extends laterally in core array region 101 and conductive portion 105 of connection region 103, but are discontinuous (e.g., being replaced by second dielectric layers 205) in dielectric portion 107 of connection region 103, according to some implementations.

The conductive layers can include conductive materials including, but not limited to, tungsten (W), cobalt (Co), copper (Cu), aluminum (Al), titanium nitride (TiN), polycrystalline silicon (polysilicon), doped silicon, silicides, or any combination thereof. First dielectric layers 203 or second dielectric layers 205 can include dielectric materials including, but not limited to, silicon oxide, silicon nitride, silicon oxynitride, or any combination thereof. First dielectric layers 203 and second dielectric layers 205 can have different dielectric materials, such as silicon oxide and silicon nitride. In some implementations, the conductive layers include metals, such as tungsten, first dielectric layers 203 include silicon oxide, and second dielectric layers 205 include silicon nitride. For example, first dielectric layers 203 of stack structure 201 may include silicon oxide across core array region 101 and connection region 103. The first layers of stack structure 201 may include tungsten (W) in core array region 101 and conductive portion 105 of connection region 103, and may include silicon nitride in dielectric portion 107 of connection region 103.

In some implementations, stack structure 201 may be formed over a semiconductor layer 207, such as a substrate. The substrate can include silicon (e.g., single crystalline silicon), silicon germanium (SiGe), gallium arsenide (GaAs), germanium (Ge), silicon on insulator (SOI), or any other suitable materials. In some implementations, the substrate includes single crystalline silicon, which is part of the wafer on which memory device 200 is fabricated, either in its native thickness or being thinned. In some implementations, the substrate includes, for example, polysilicon, which is a semiconductor layer replacing the part of the wafer on which memory device 200 is fabricated.

It is noted that x, y, and z axes are included in FIGS. 1 and 2A to illustrate the spatial relationship of the components in the memory device. Semiconductor layer 207 (e.g., the substrate) includes two lateral surfaces extending laterally in the x-y plane: a top surface on the front side of the wafer on which stack structure 201 can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of the 3D memory device is determined relative to semiconductor layer 207 in the z-direction (the vertical direction perpendicular to the x-y plane) when semiconductor layer 207 is positioned in the lowest plane of the memory device in the z-direction. The same notion for describing the spatial relationship is applied throughout the present disclosure.

As shown in FIG. 2A, contact structure 106 extends vertically into stack structure 201 in dielectric portion 107 of connection region 103, according to some implementations. The top surfaces of different contact structures 106 can be flush with one another, while the bottom surfaces of different contact structures 106 can extend to different levels, for example, different second dielectric layers 205 of stack structure 201. In some implementations, contact structure 106 may extend into the first portion of stack structure 201 in the z-direction and connect to a corresponding conductive layer 275 (e.g., a corresponding gate line). For example, contact structure 106 may include a lateral contact member 277 located in the same layer as the corresponding conductive layer 275 and connected to the corresponding conductive layer 275. An enlarged view of contact structure 106 is shown in FIG. 2B.

In some examples, conductive layers 275 may be formed by replacing parts of second dielectric layers 205 in the second portion of stack structure 201 with W layers. The W layers are surrounded by high-k gate dielectric layers 276 (e.g., AlO) as shown in FIG. 2B, and adjacent W layers are separated by first dielectric layers 203 (e.g., silicon oxide). As described above, when WF6 is used to deposit the W layers into stack structure 201, Fluoride ions (F−) may be left in the W layers. In a subsequent thermal process, these Fluoride ions (F−) may be diffused and replace the O bonds (—O) in silicon oxide and AlO to form Si—F bonds and Al—F bonds, respectively, causing the structure of silicon oxide (e.g., first dielectric layers 203) and the structure of AlO (e.g., high-k gate dielectric layers 276) become instable. When a large volume of free H ions (H+) are provided in an environment of the thermal process, the F ions (F−) may be combined with the H ions (H+), causing damages to the structure of silicon oxide and the structure of AlO. Then, the anti-breakdown ability of the structure of silicon oxide is degraded, which may result in leakage between the gate lines (e.g., the W layers).

For example, during a thermal process, a slight creak or bubble may appear in a connection interface 287 where contact structure 106 connects to a respective W layer, due to the stress changes on the material filled in the contact structure. Meanwhile, contact structure 106 may be squeezed by the W layer and array common source (ACS) poly, resulting in a structural instability of contact structure 106 and the W layer. In the thermal process, the hot temperature may provide power for the F ions (F−) to diffuse, and a H+rich environment in the thermal process will cause F− to combine with H+. As a result, the structure of silicon oxide (e.g., first dielectric layers 203) and the structure of AlO (e.g., high-k gate dielectric layers 276) can be damaged, causing leakage between conductive layers 275 (the W layers). Then, severe yield loss may occur.

FIG. 3A illustrates a cross-sectional side view of a memory device 300 having contact structures 106, according to some aspects of the present disclosure. Memory device 300 can be an example of memory device 100 in FIG. 1. One cross-section may be along the BB direction in core array region 101 in FIG. 1, and another cross-section may be along the AA direction in connection region 103 in FIG. 1. As shown in FIG. 3A, memory device 300 can include channel structures 110 in core array region 101. Each channel structure 110 can extend vertically through interleaved conductive layers 275 (gate lines, e.g., tungsten) and first dielectric layers 203 (e.g., silicon oxide) in core array region 101 of stack structure 201 into semiconductor layer 207. Memory device 300 can also include dummy channel structures 112 in conductive portion 105 of connection region 103. Each dummy channel structure 112 can extend vertically through interleaved conductive layers 275 and first dielectric layers 203 in core array region 101 into semiconductor layer 207. Memory device 300 can further include slit structures 108 across core array region 101 and core array region 101. Each slit structure 108 can extend vertically through interleaved conductive layers 275 and first dielectric layers 203 in the second portion of stack structure 201 into semiconductor layer 207 as well.

In some implementations, channel structure 110 includes a channel hole filled with a semiconductor layer (e.g., as a channel layer) and a composite dielectric layer (e.g., as a memory layer). In some implementations, the channel layer includes silicon, such as amorphous silicon, polysilicon, or single crystalline silicon. For example, the channel layer may include polysilicon. In some implementations, the memory layer is a composite layer including a tunneling layer, a storage layer (also known as a “charge trap layer”), and a blocking layer. The remaining space of the channel hole can be partially or fully filled with a filler including dielectric materials, such as silicon oxide, and/or an air gap. Channel structure 110 can have a cylinder shape (e.g., a pillar shape). The filler, the channel layer, the tunneling layer, the storage layer, and the blocking layer are arranged radially from the center toward the outer surface of the pillar in this order, according to some implementations. The tunneling layer can include silicon oxide, silicon oxynitride, or any combination thereof. The storage layer can include silicon nitride, silicon oxynitride, silicon, or any combination thereof. The blocking layer can include silicon oxide, silicon oxynitride, or any combination thereof. In one example, the memory layer can include a composite layer of silicon oxide/silicon oxynitride/silicon oxide (ONO).

In some implementations, dummy channel structure 112 has the same structure as channel structure 110 because they are formed in the same fabrication process. Dummy channel structure 112, however, cannot perform the same memory functions as channel structure 110 at least because dummy channel structures 112 are not in contact with any drain select gate (DSG) channel structures 307 or any local contacts (e.g., channel contacts 306) in the local contact layer to pick-up/fan-out dummy channel structures 112, as shown in FIG. 3A, according to some implementations. It is understood that in some examples, dummy channel structures 112 and channel structure 110 may have different structures and may be formed in different fabrication processes. For example, dummy channel structures 112 may be filled with dielectric material(s) without semiconductor materials (as the channel layer). Nevertheless, both dummy channel structures 112 and channel structures 110 can perform the mechanical supporting functions to stack structure 201, in particular, during the gate replacement process, as described below in detail with respect to the fabrication processes.

As shown in FIG. 3A, in some implementations, memory device 300 further includes a plurality of drain select gate (DSG) channel structures 307 above and in contact with the upper ends of channel structures 110, respectively. Memory device 300 can further include a DSG layer 304 including a semiconductor layer (e.g., polysilicon layer) on stack structure 201 in core array region 101, but not in connection region 103, for example, as shown in FIG. 3A. Each DSG channel structure 307 can extend vertically through DSG layer 304 to be in contact with the upper end of a corresponding channel structure 110. In some implementations, memory device 300 further includes a stop layer 311 (e.g., silicon nitride layer) on DSG layer 304. DSG channel structure 307 can include a semiconductor layer (e.g., polysilicon) and a spacer surrounding the semiconductor layer. In some implementations, memory device 300 includes a DSG stack including one or more DSG layers and one or more dielectric layers (e.g., silicon oxide layers) interleaved stacked above stack structure 201.

As shown in FIG. 3A, memory device 300 can further include a local contact layer above stop layer 311 and stack structure 201. In some implementations, the local contact layer includes various local contacts, such as channel contacts 306 (a.k.a. bit line contacts) above and in contact with DSG channel structures 307 in core array region 101. The local contact layer can further include one or more interlayer dielectric (ILD) layers (also known as “intermetal dielectric (IMD) layers”) in which the local contacts can form. Channel contacts 306 in the local contact layer can include conductive materials including, but not limited to, W, Co, Cu, Al, silicides, or any combination thereof. The ILD layers in the local contact layer can include dielectric materials including, but not limited to, silicon oxide, silicon nitride, silicon oxynitride, low-k dielectrics, or any combination thereof.

As shown in FIG. 3A, slit structure 108 can include a slit spacer 309 that separates conductive layers 275 (gate lines) between different blocks 102. In some implementations, slit structure 108 is an insulating structure that does not include any contact therein (i.e., not functioning as the source contact) and thus, does not introduce parasitic capacitance and leakage current with conductive layers 275 (gate lines). In some implementations, slit structure 108 is a front-side source contact further including a conductive portion (e.g., including W, polysilicon, and/or TiN) circumscribed by slit spacer 309. As described below in detail, during the gate replacement process, the slit in which slit structure 108 is formed can serve as the passageway and starting point for forming conductive layers 275. As a result, slit structure 108 is surrounded by conductive layers 275 in either core array region 101 or conductive portion 105 of connection region 103.

As shown in FIG. 3A, memory device 300 may further include contact structures 106 extending into the first portion of stack structure 201 in the z-direction. As described below in detail, during the gate replacement process, some of second dielectric layers 205 (e.g., silicon nitride) remain intact in dielectric portion 107 of connection region 103, and contact structures 106 are formed by etching first and second dielectric layers 203 and 205 in dielectric portion 107. As a result, contact structures 106 extend into interleaved first and second dielectric layers 203 and 205 and are surrounded by first and second dielectric layers 203 and 205 in dielectric portion 107 of connection region 103. A third contact member 358 (e.g., a lateral contact member) of each contact structure 106 can be aligned with a corresponding second dielectric layer 205, as opposed to first dielectric layer 203, and the corresponding second dielectric layer 205 can be partially replaced with third contact member 358 to form the electrical connection between a first contact member 354 of contact structure 106 and the corresponding conductive layer 275 (gate line). Thus, in some implementations, third contact member 358 is sandwiched between two first dielectric layers 203, as opposed to two second dielectric layers 205, in dielectric portion 107 of connection region 103.

Memory device 300 can further include high dielectric constant (high-k) gate dielectric layers 342 each sandwiched between adjacent conductive layer 275 and first dielectric layer 203 in core array region 101 and conductive portion 105 of connection region 103. As described below in detail with respect to the fabrication process, high-k gate dielectric layers 342 may be formed prior to the formation of conductive layers 275, such that conductive layers 275 may be formed surrounded by high-k gate dielectric layers 342. High-k gate dielectric layers 342 can include high-k dielectric materials, such as aluminum oxide (AlO), hafnium oxide (HfO), zirconium oxide (ZrO), or any combinations thereof. As shown in FIG. 3A, compared with other high-k gate dielectric layers 342, part of high-k gate dielectric layer 342 surrounding conductive layer 275A (part of gate line) that is in contact with third contact member 358 of contact structure 106 is removed to expose conductive layer 275 such that third contact member 358 can be electrically connected to conductive layer 275A.

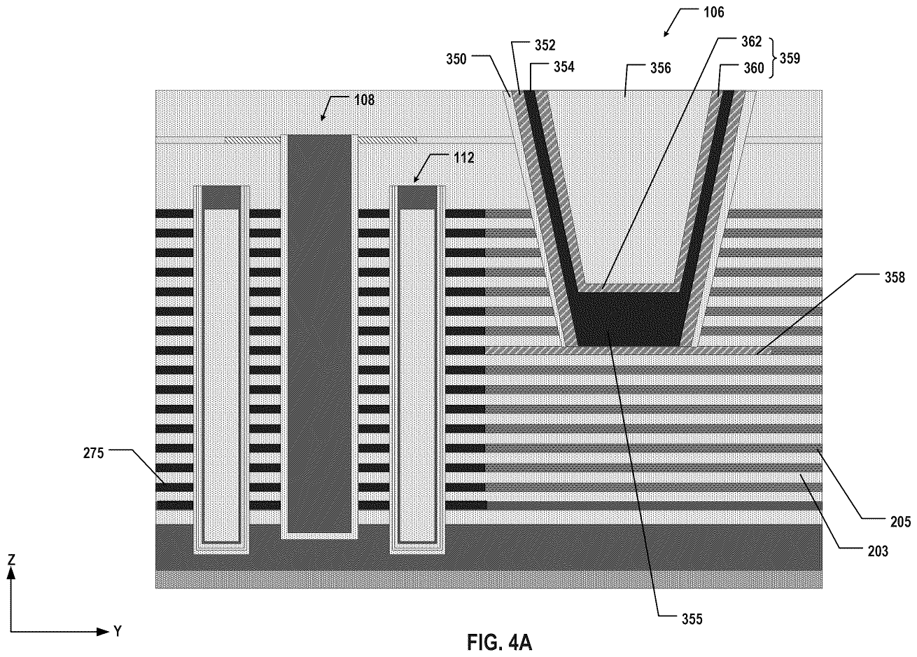

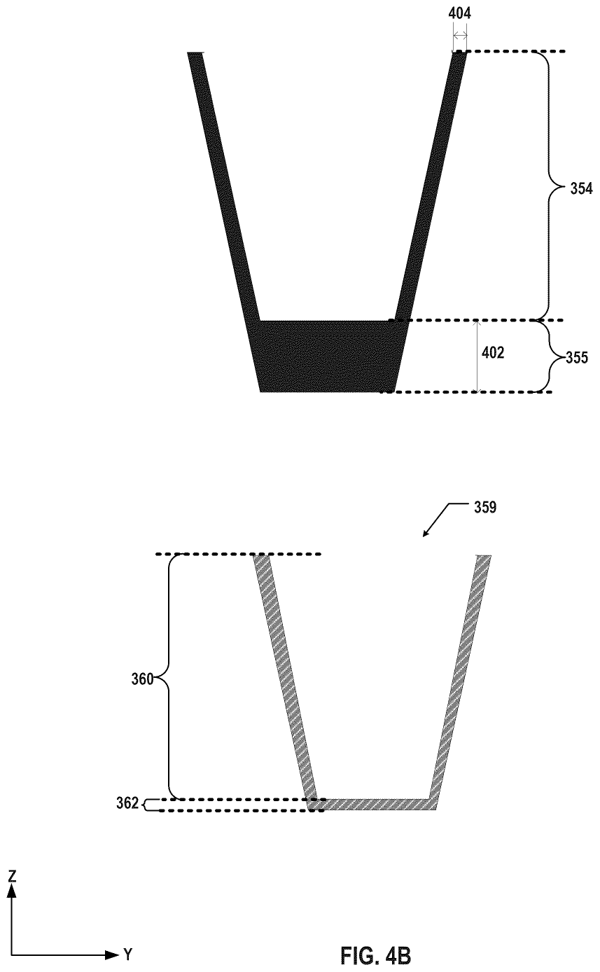

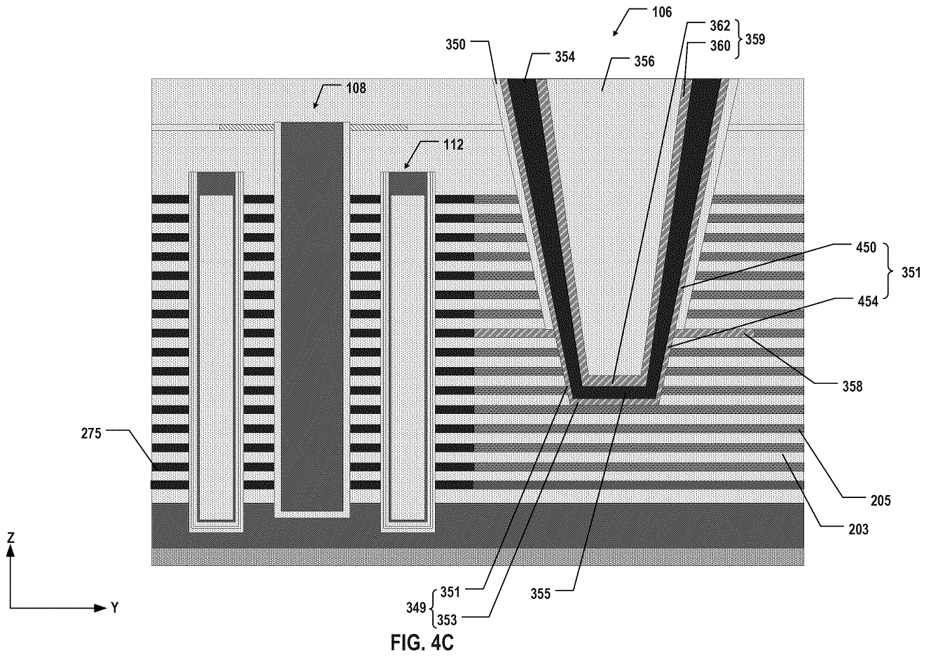

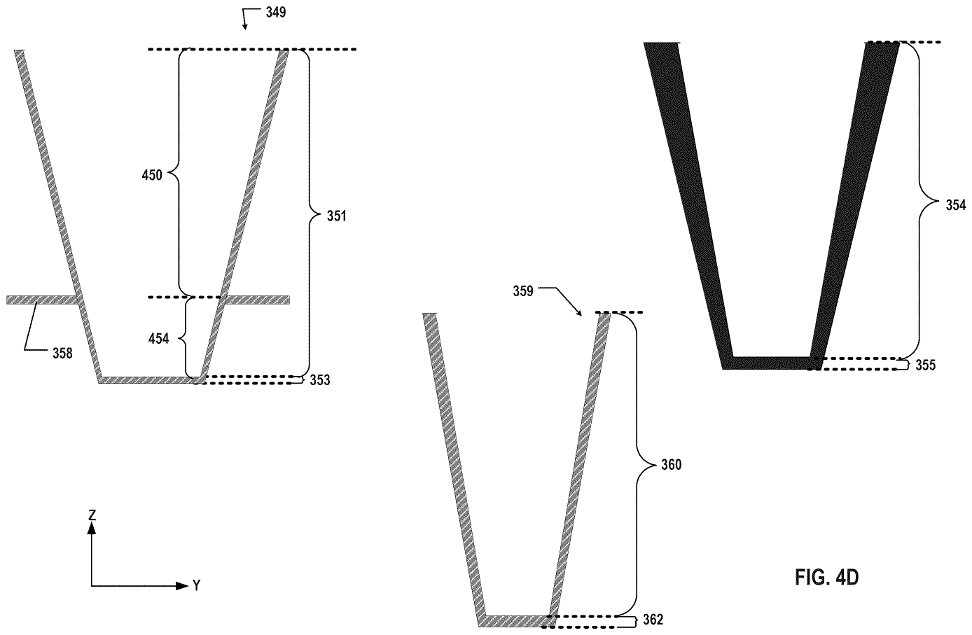

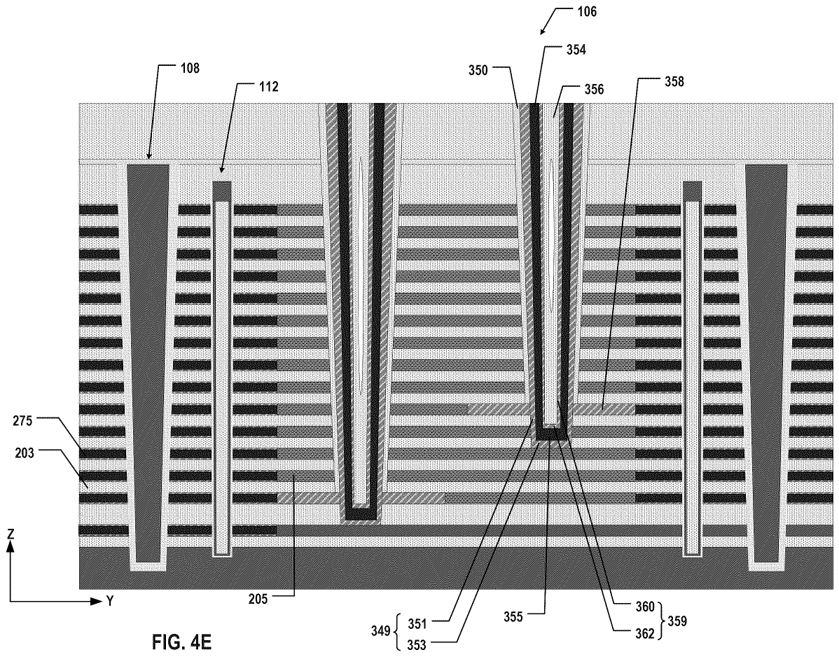

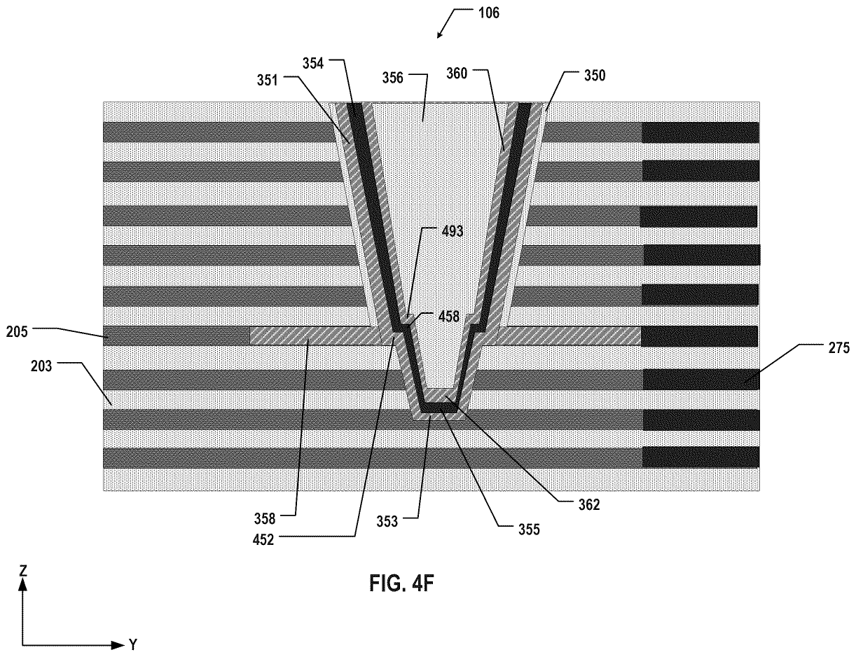

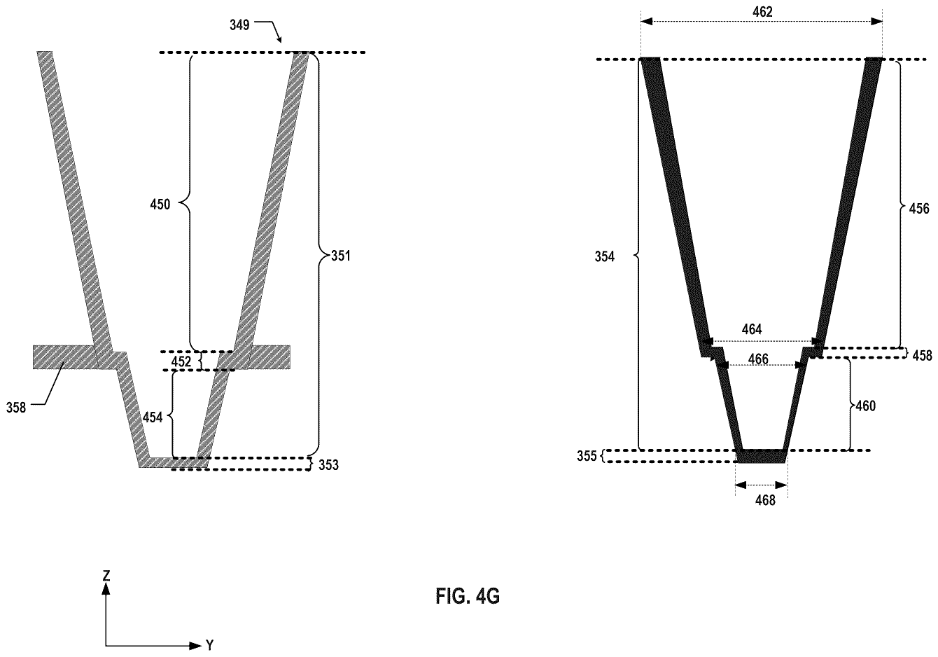

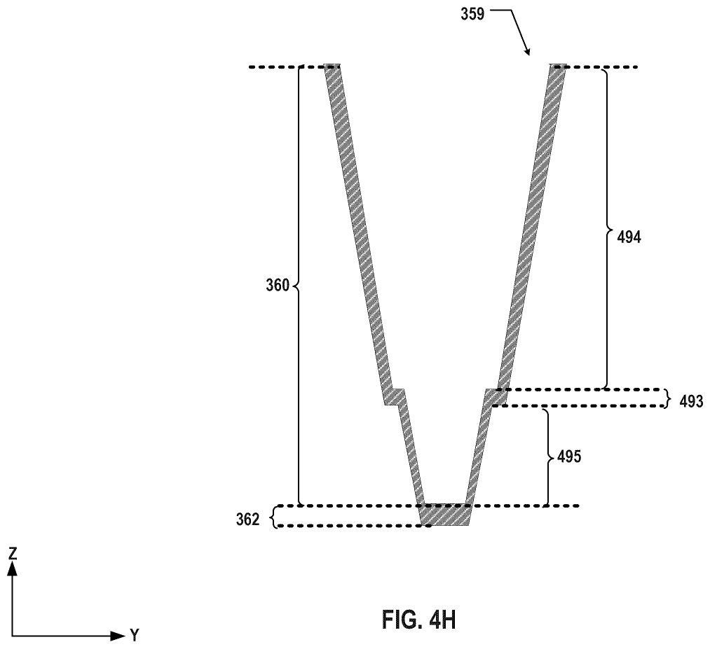

A first structure design of contact structure 106 is illustrated in FIGS. 3A and 4A-4B. In the first structure design, contact structure 106 may include (i) a first contact member 354 extending in the z-direction, (ii) a second contact member 355 connecting to an end (e.g., a bottom end) of first contact member 354 and extending in the y-direction, and (iii) a third contact member 358 extending in the y-direction and connecting to second contact member 355. For example, second contact member 355 is below the bottom end of first contact member 354 and in contact with the bottom end of first contact member 354. Third contact member 358 is below second contact member 355 and in contact with second contact member 355. Third contact member 358 may be in the same layer as a conductive layer 275A and connects to conductive layer 275A. As shown in FIG. 3A or FIGS. 4A-4B, contact structure 106 may further include an outer metal layer 352 extending in the z-direction and surrounding first contact member 354. Outer metal layer 352 may also surround second contact member 355. Contact structure 106 may further include a contact spacer 350 extending in the z-direction and surrounding outer metal layer 352.

Each of first, second, and third contact members 354, 355, and 358 and outer metal layer 352 can include conductive materials including, but not limited to, W, Co, Cu, Al, TiN, polysilicon, doped silicon, silicides, or any combination thereof. Contact spacer 350 can include dielectric materials including, but not limited to, silicon oxide, silicon nitride, silicon oxynitride, or any combination thereof. In some implementations, first and second contact members 354 and 355 may include W; third contact member 358 and outer metal layer 352 may include TiN; and contact spacer 350 can include silicon oxide. When outer metal layer 352 and third contact member 358 are formed with the same conductive material, the boundary between them is invisible.

In some implementations, contact structure 106 further includes a filler 356 circumscribed by first contact member 354. That is, a contact hole may not be fully filled with contact spacer 350, outer metal layer 352, first contact member 354, and second contact member 355. The remaining space of the contact hole may be filled with dielectric materials, including, but not limited to, silicon oxide, silicon nitride, silicon oxynitride, or any combination thereof, as filler 356. In some implementations, a gap structure 357 may be provided in filler 356. For example, filler 356 may include an air gap.

In some implementations, as shown in FIG. 4B, a first thickness 402 of second contact member 355 in the z-direction is greater than a second thickness 404 of first contact member 354 in the y-direction. In some implementations, first contact member 354 may have a uniform thickness 404 in the y-direction. Alternatively, first contact member 354 may have a non-uniform thickness in the y-direction. Second thickness 404 of first contact member 354 can be, for example, a maximal thickness of first contact member 354 in the y-direction. In some implementations, first thickness 402 of second contact member 355 in the z-direction is equal to or greater than a thickness of two or more layers from first and second dielectric layers 203 and 205 in the z-direction. For example, a range of first thickness 402 of second contact member 355 is between (a) a thickness of two layers from first and second dielectric layers 203 and 205 and (b) a thickness of twenty layers from first and second dielectric layers 203 and 205 in the z-direction.

In some implementations as shown in FIGS. 4A-4B, contact structure 106 further includes an inner metal structure 359, which includes (i) a first inner metal layer 360 extending in the z-direction and surrounded by first contact member 354 and (ii) a second inner metal layer 362 extending in the z-direction. Second inner metal layer 362 may be below an end (e.g., a bottom end) of first inner metal layer 360 and connects to the end of first inner metal layer 360. Second inner metal layer 362 may cover an inner surface of second contact member 355. For example, second inner metal layer 362 may be on top of the inner surface of second contact member 355. First inner metal layer 360 and second inner metal layer 362 can include conductive materials including, but not limited to, W, Co, Cu, Al, TiN, polysilicon, doped silicon, silicides, or any combination thereof. For example, first inner metal layer 360 and second inner metal layer 362 can include TiN.

FIG. 3B illustrates cross-sectional side views of 3D memory device 300 having contact structures 106 with a second structure design, according to some aspects of the present disclosure. FIG. 3B may include components like those described above with reference to FIG. 3A, and a similar description will not be repeated herein. With respect to the second structure design shown in FIGS. 3B and 4C-4G, contact structure 106 may include (i) first contact member 354 extending in the z-direction, (ii) second contact member 355 connecting to a first end (e.g., the bottom end) of first contact member 354 and extending in the y-direction, and (iii) third contact member 358 extending in the y-direction and connecting to first contact member 354. Third contact member 358 may be located between the first end (e.g., the bottom end) and a second end (e.g., the top end) of first contact member 354. Third contact member 358 may be in the same layer as conductive layer 275A and connects to conductive layer 275A.

For example, second contact member 355 is below the bottom end of first contact member 354 and in contact with the bottom end of first contact member 354. Third contact member 358 and second contact member 355 can be spaced apart by one or more layers from first and second dielectric layers 203 and 205 in the z-direction. In some implementations, a part of first contact member 354, as well as the entire second contact member 355, is below third contact member 358 in the z-direction.

As shown in FIG. 3B or FIGS. 4C-4G, contact structure 106 may further include an outer metal structure 349, which may surround first contact member 354 and second contact member 355. For example, outer metal structure 349 may cover an outer surface of first contact member 354 and an outer surface of second contact member 355. Outer metal structure 349 includes (i) a first outer metal layer 351 extending in the z-direction and surrounding first contact member 354 and (ii) a second outer metal layer 353 extending in the y-direction and covering an outer surface of second contact member 355. Second outer metal layer 353 may connect to a first end (e.g., the bottom end) of first outer metal layer 351. For example, second outer metal layer 353 may be below the first end of first outer metal layer 351 and in contact with the first end of first outer metal layer 351. In some implementations, third contact member 358 connects to first outer metal layer 351 between the first end (e.g., the bottom end) and a second end (e.g., the top end) of first outer metal layer 351. For example, third contact member 358 connects to the middle of first outer metal layer 351. In some implementations, a part of first outer metal layer 351, as well as the entire second outer metal layer 353, is below third contact member 358 in the z-direction.

In some implementations, as shown in FIGS. 4C-4D, first outer metal layer 351 may include a first outer segment 450 and a second outer segment 454. First outer segment 450 is located on a first side (e.g., an upper side) of third contact member 358 that is away from second contact member 355. Second outer segment 454 is located on a second side (e.g., a lower side) of third contact member 358 that is close to second contact member 355 and opposite to the first side. Contact structure 106 may further include a contact spacer 350 extending in the z-direction and surrounding first outer segment 450. Second outer segment 454 is not surrounded by contact spacer 350.

In some implementations, first, second and third contact members 354, 355, and 358, as well as first and second outer metal layers 351 and 353, can include conductive materials including, but not limited to, W, Co, Cu, Al, TiN, polysilicon, doped silicon, silicides, or any combination thereof. Contact spacer 350 can include dielectric materials including, but not limited to, silicon oxide, silicon nitride, silicon oxynitride, or any combination thereof. In some implementations, first and second contact members 354 and 355 may include W; third contact member 358, first outer metal layer 351, and second outer metal layer 353 may include TiN; and contact spacer 350 can include silicon oxide. When first outer metal layer 351 and third contact member 358 include the same conductive material, a boundary between first outer metal layer 351 and third contact member 358 may not be visible.

In some implementations, contact structure 106 further includes filler 356 circumscribed by first contact member 354. Filler 356 may include a dielectric material, including, but not limited to, silicon oxide, silicon nitride, silicon oxynitride, or any combination thereof, as filler 356. In some implementations, gap structure 357 may be provided in filler 356.

In some implementations as shown in FIGS. 4C-4F and 4H, contact structure 106 further includes inner metal structure 359 surrounded by first contact member 354 and second contact member 355. Inner metal structure 359 includes (i) first inner metal layer 360 extending in the z-direction and surrounded by first contact member 354 and (ii) second inner metal layer 362 extending in the z-direction and covering an inner surface of second contact member 355. Second inner metal layer 362 may be below an end (e.g., a bottom end) of first inner metal layer 360, and connects to the end of first inner metal layer 360. First inner metal layer 360 and second inner metal layer 362 can include conductive materials including, but not limited to, W, Co, Cu, Al, TiN, polysilicon, doped silicon, silicides, or any combination thereof. For example, first inner metal layer 360 and second inner metal layer 362 can include TiN.

In some implementations, as shown in FIGS. 4F-4G, first outer metal layer 351 may further include an outer metal shoulder 452 between first outer segment 450 and second outer segment 454. First contact member 354 may include a first contact segment 456, a contact shoulder 458, and a second contact segment 460. Contact shoulder 458 may be formed on outer metal shoulder 452. Contact shoulder 458 may connect to first contact segment 456 and second contact segment 460. First contact segment 456 is located on a first side (e.g., an upper side) of third contact member 358 that is away from second contact member 355. Second contact segment 460 connects to second contact member 355, and is located on a second side (e.g., a lower side) of third contact member 358 that is opposite to the first side.

As shown in FIG. 4G, in the y-direction, a size 462 of a first end of first contact segment 456 that is away from contact shoulder 458 is greater than a size 464 of a second end of first contact segment 456 that connects to contact shoulder 458. Size 464 of the second end of first contact segment 456 is greater than a size 466 of a first end of second contact segment 460 that also connects to contact shoulder 458. Size 466 of the first end of second contact segment 460 is greater than a size 468 of a second end of second contact segment 460 that is away contact shoulder 458.

As shown in FIGS. 4F and 4H, first inner metal layer 360 may include a first inner segment 494, an inner metal shoulder 493 located on contact shoulder 458, and a second inner segment 495. Inner metal shoulder 493 may connect to first inner segment 494 and second inner segment 495. First inner segment 494 is located on the first side (e.g., the upper side) of third contact member 358 that is away from second contact member 355. Second inner segment 495 connects to second contact member 355, and is located on the second side (e.g., the lower side) of third contact member 358 that is opposite to the first side.

In some implementations, in the second structure design shown in FIGS. 3B and 4C-4G, a thickness of second contact member 355 in the z-direction can also be increased, such that the thickness of second contact member 355 in the z-direction is greater than a thickness of first contact member 354 in the y-direction like that of FIGS. 3A and 4A-4B.

With combined reference to FIGS. 3A and 3B, instead of having staircase structures and contacts landed on different levels/stairs of the staircase structures, memory device 300 can include stack structure 201 with uniform heights and contact structures 106 in dielectric portion 107 of connection region 103 for word line pick-up/fan-out. As shown in FIGS. 3A-3B, third contact member 358 of each contact structure 106 in dielectric portion 107 can extend laterally in the y-direction (the bit line direction) to be in contact with a corresponding conductive layer 275 (gate line) in conductive portion 105 at the same level of stack structure 201. That is, each contact structure 106 is electrically connected to the corresponding conductive layer 275 (gate line) across conductive portion 105 in connection region 103 and core array region 101, according to some implementations. A plurality of contact structures 106 can extend vertically through stack structure 201 at different depths to be electrically connected to the gate lines at different levels, respectively, to achieve word line pick-up/fan-out.

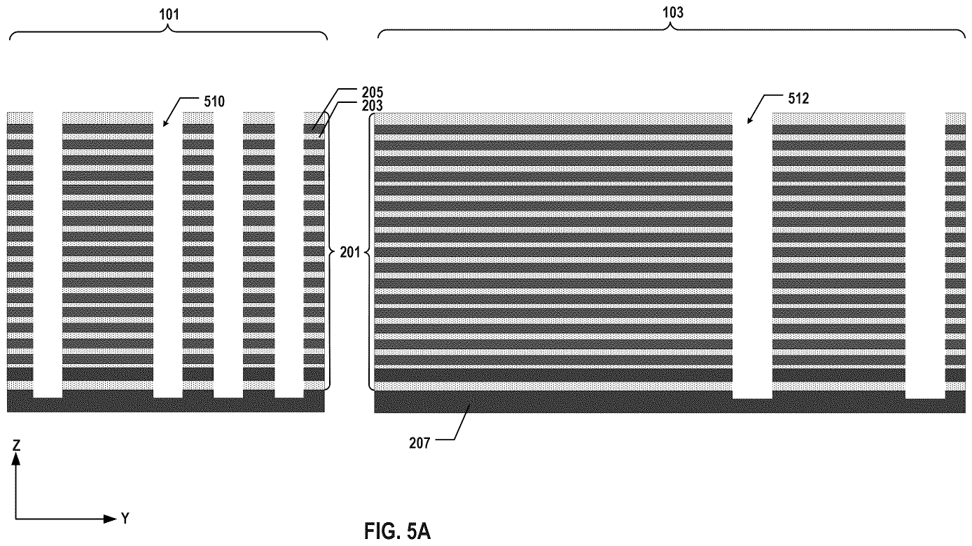

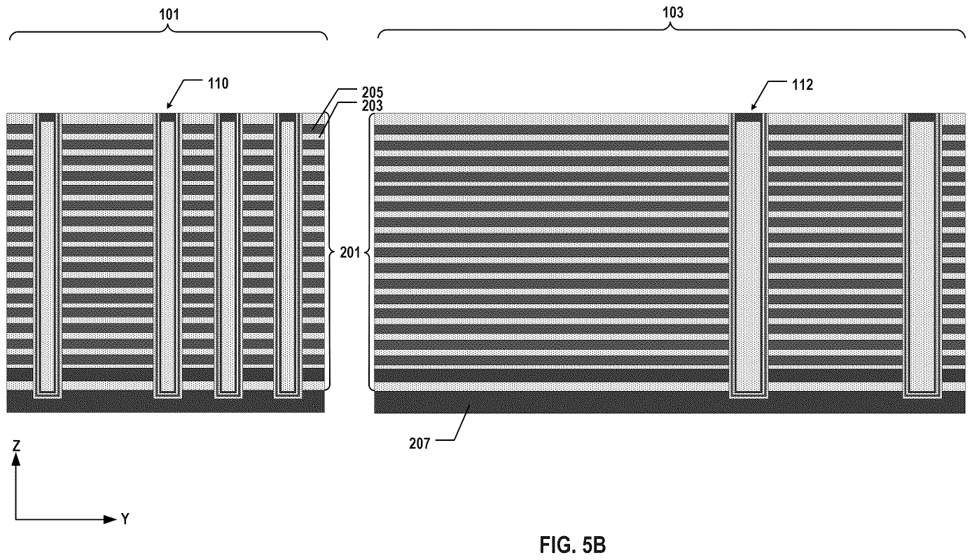

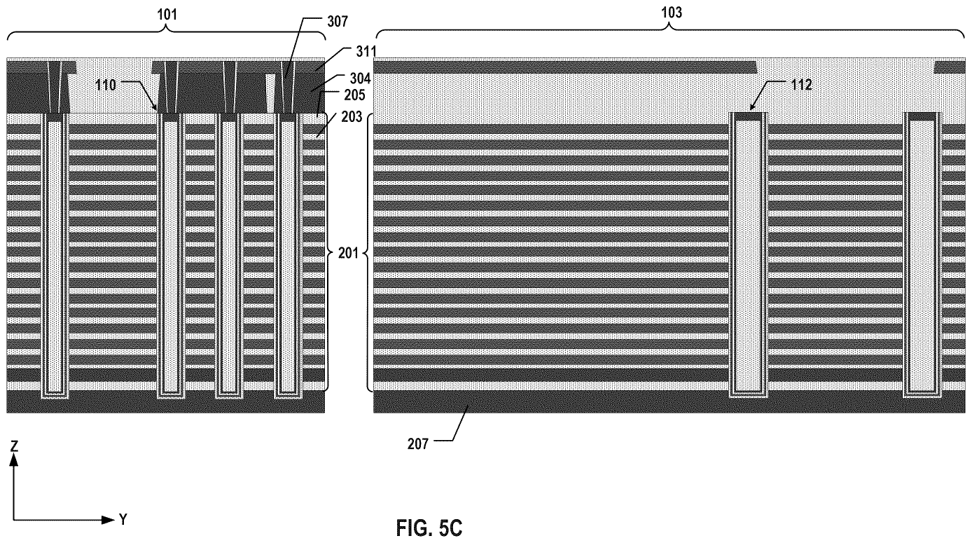

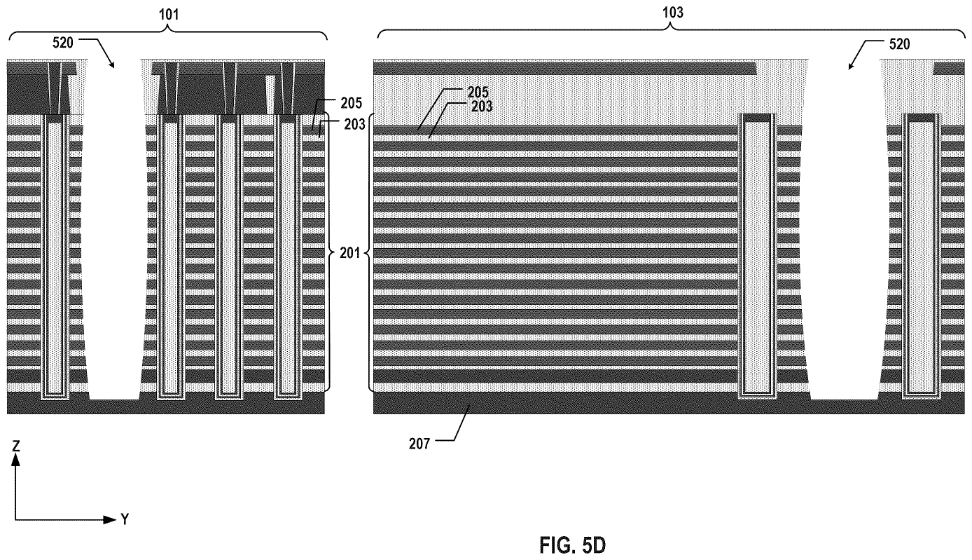

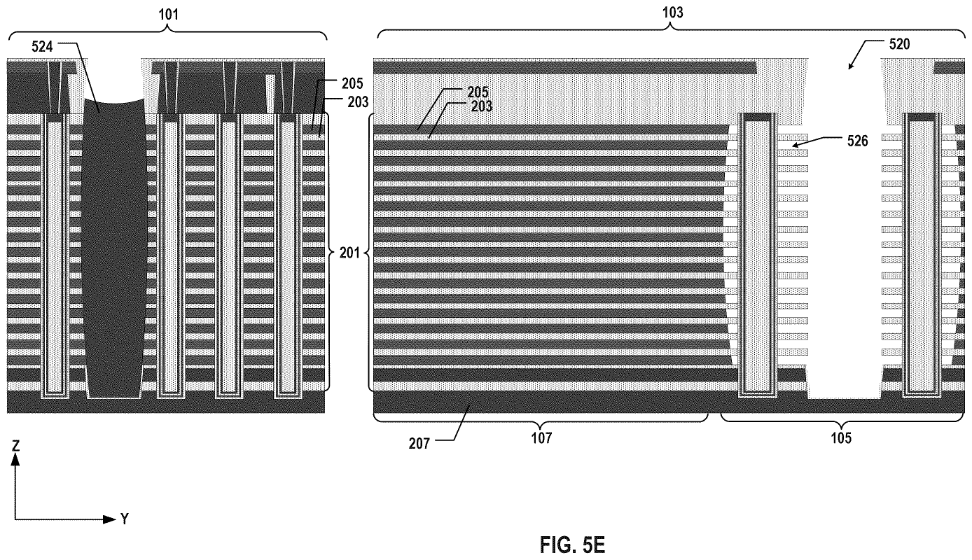

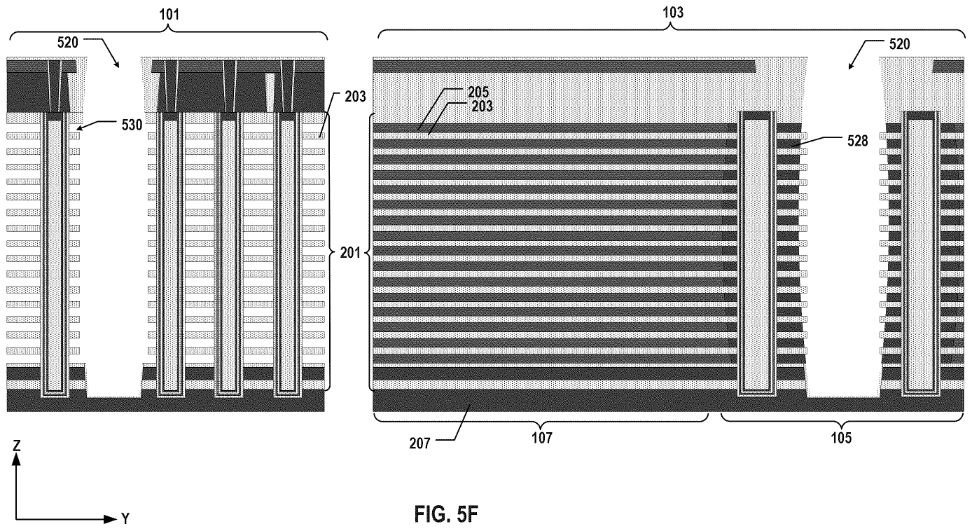

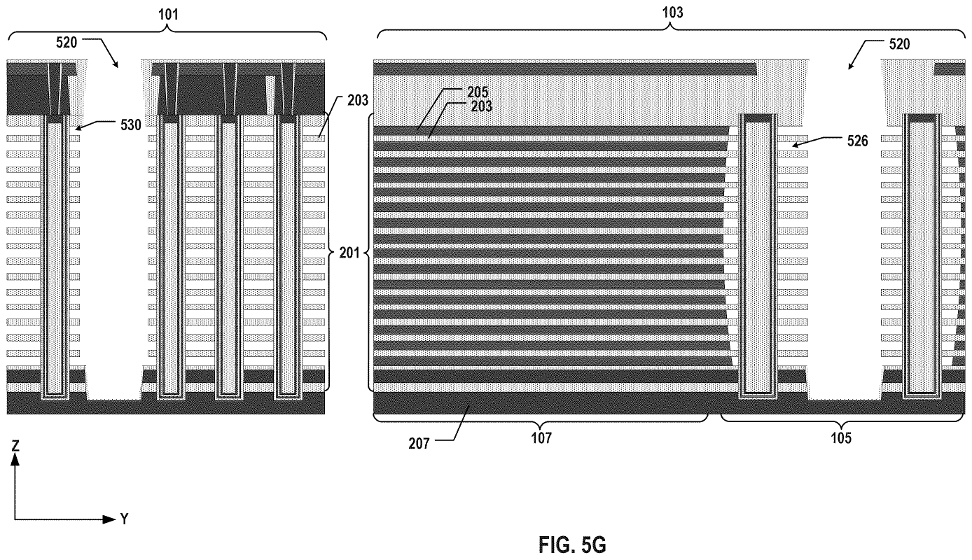

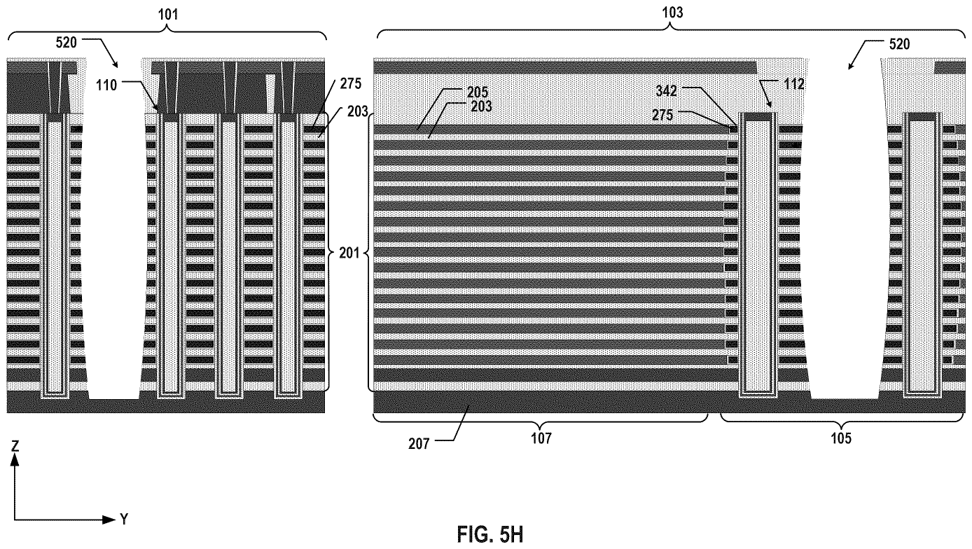

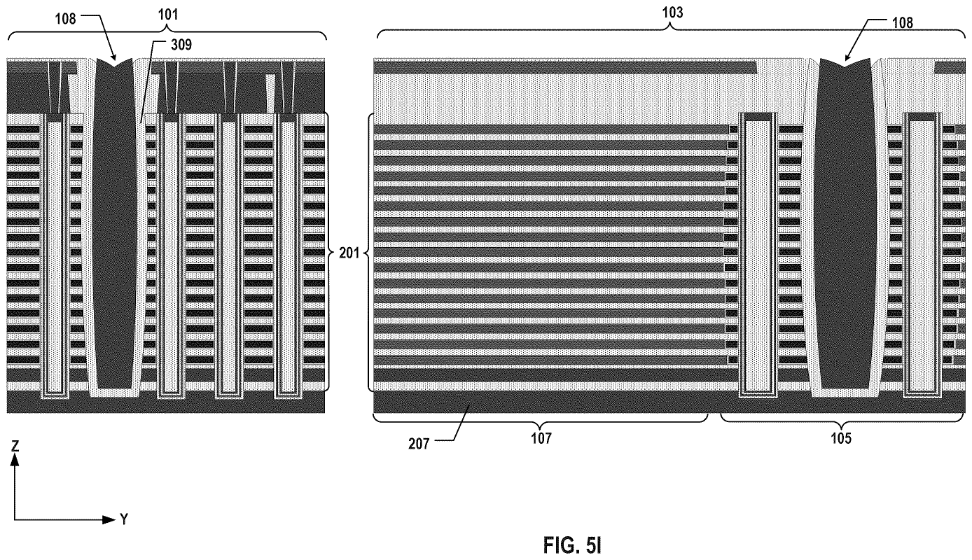

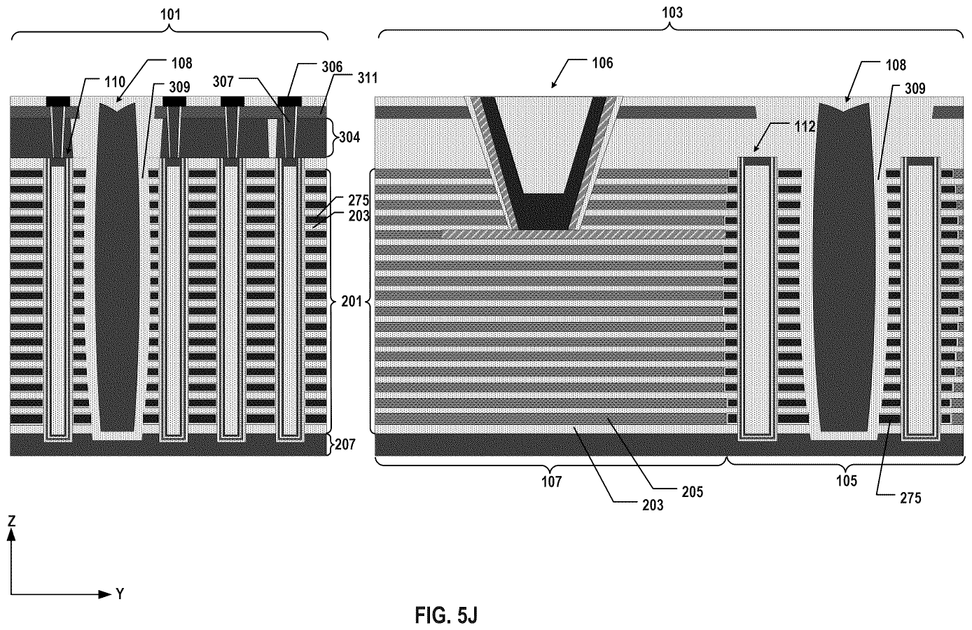

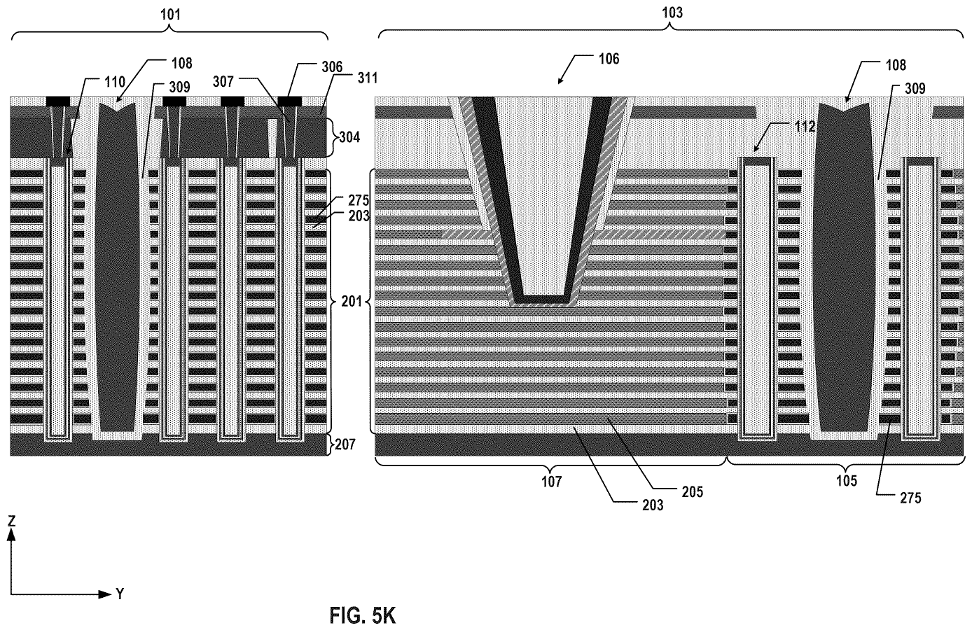

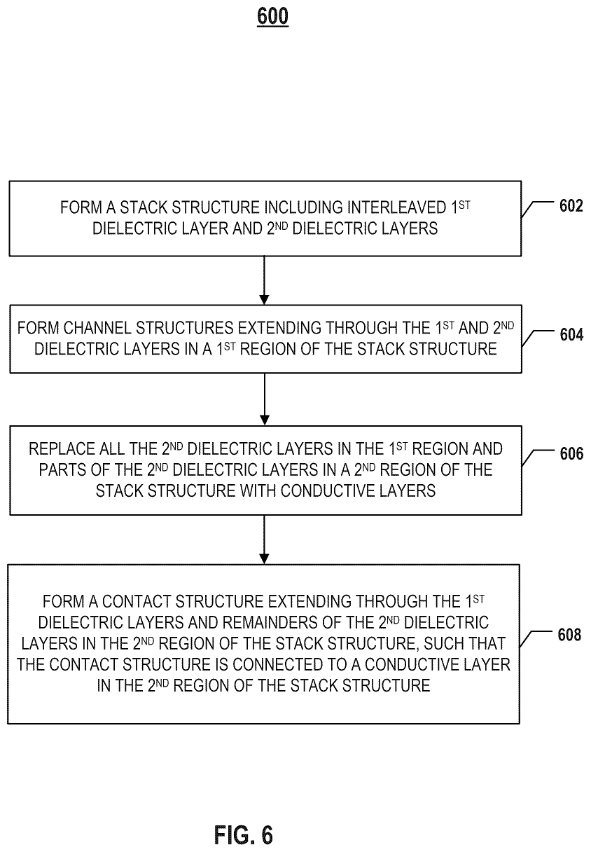

FIGS. 5A-5K illustrate a fabrication process for forming memory device 300 having contact structures, according to some aspects of the present disclosure. FIG. 6 is a flowchart of a method 600 for forming memory device 300 having contact structures 106, according to some aspects of the present disclosure. FIGS. 5A-5K and 6 will be described together. It is understood that the operations shown in method 600 are not exhaustive and that other operations can be performed as well before, after, or between any of the illustrated operations. Further, some of the operations may be performed simultaneously, or in a different order than shown in FIG. 6.

Referring to FIG. 6, method 600 starts at operation 602, in which a stack structure including interleaved first dielectric layers and second dielectric layers is formed. The first dielectric layers can include silicon oxide, and the second dielectric layers can include silicon nitride. In some implementations, to form the stack structure, the first dielectric layers and the second dielectric layers are alternatingly deposited above a semiconductor layer, such as a substrate. The substrate can be a silicon substrate.

Method 600 proceeds to operation 604, as illustrated in FIG. 6, in which channel structures extending through the first dielectric layers and the second dielectric layers are formed in a first region of the stack structure. In some implementations, to form the channel structure, a channel hole extending vertically through the stack structure is formed, and a memory layer and a channel layer are sequentially formed over sidewalls of the channel hole. In some implementations, dummy channel structures extending through the first dielectric layers and the second dielectric layers are formed in a second region of the stack structure in the same process of forming the channel structures. That is, channel structures and dummy channel structures can be simultaneously formed through the first dielectric layers and the second dielectric layers in the first region and the second region of the stack structure, respectively.

As illustrated in FIG. 5A, stack structure 201 including multiple pairs of a first dielectric layer 203 and a second dielectric layer 205 (a.k.a., a stack sacrificial layer) is formed above semiconductor layer 207. Stack structure 201 includes vertically interleaved first dielectric layers 203 and second dielectric layers 205, according to some implementations. First and second dielectric layers 203 and 205 can be alternatingly deposited above semiconductor layer 207 to form stack structure 201. In some implementations, each first dielectric layer 203 includes a layer of silicon oxide, and each second dielectric layer 205 includes a layer of silicon nitride. Stack structure 201 can be formed by one or more thin film deposition processes including, but not limited to, chemical vapor deposition (CVD), physical vapor deposition (PVD), atomic layer deposition (ALD), or any combination thereof.

Channel holes 510, each of which is an opening extending vertically through stack structure 201, can be formed in core array region 101. In some implementations, a plurality of openings are formed, such that each opening becomes the location for growing an individual channel structure 110 in the later process. In some implementations, fabrication processes for forming channel holes 510 of channel structure 110 include wet etching and/or dry etching, such as deep-ion reactive etching (DRIE). A dummy channel hole 512, which is another opening extending vertically through stack structure 201, can be formed in connection region 103 simultaneously as channel hole 510 by the same wet etching and/or dry etching, such as DRIE.

As illustrated in FIG. 5B, channel structures 110 can be formed in channel holes 510 in core array region 101 of stack structure 201. A memory layer (including a blocking layer, a storage layer, and a tunneling layer) and a channel layer are sequentially formed in this order along sidewalls and the bottom surface of channel hole 510. In some implementations, the memory layer is first deposited along the sidewalls and bottom surface of channel hole 510, and the semiconductor channel is then deposited over the memory layer. The blocking layer, storage layer, and tunneling layer can be subsequently deposited in this order using one or more thin film deposition processes, such as ALD, CVD, PVD, any other suitable processes, or any combination thereof, to form the memory layer. The channel layer can then be formed by depositing a semiconductor material, such as polysilicon, over the tunneling layer of the memory layer using one or more thin film deposition processes, such as ALD, CVD, PVD, any other suitable processes, or any combination thereof. In some implementations, a first silicon oxide layer, a silicon nitride layer, a second silicon oxide layer, and a polysilicon layer (a “SONO” structure) are subsequently deposited to form the memory layer and the channel layer of channel structure 110.

In some implementations, as illustrated in FIG. 5B, dummy channel structure 112 can be formed in dummy channel hole 512 in connection region 103 of stack structure 201, in the same process of forming channel structures 110. Dummy channel structure 112 can be formed simultaneously as channel structure 110 by the same thin film deposition processes, such as ALD, CVD, PVD, any other suitable processes, or any combination thereof that deposit a memory layer (including a blocking layer, a storage layer, and a tunneling layer) and a channel layer. It is understood that in some examples, dummy channel structure 112 may be formed in a separate process from channel structures 110.

As illustrated in FIG. 5C, DSG layer 304 and stop layer 311 are formed on core array region 101 of stack structure 201. DSG layer 304 can include a semiconductor layer, such as a polysilicon layer, and stop layer 311 can include a silicon nitride layer. DSG layer 304 and stop layer 311 can be sequentially deposited on core array region 101, but not on connection region 103, of stack structure 201 using one or more thin film deposition processes including, but not limited to, CVD, PVD, ALD, or any combination thereof. DSG channel structures 307 can be formed extending vertically through DSG layer 304 and stop layer 311 to be in contact with the upper ends of channel structures 110, but not dummy channel structure 112, as shown in FIG. 5C. To form DSG channel structures 307, DSG holes can be etched through DSG layer 304 and stop layer 311 to expose the upper ends of channel structures 110, respectively, and a spacer (e.g., having silicon oxide) and a semiconductor layer (e.g., having polysilicon) can be sequentially deposited into the DSG holes using one or more thin film deposition processes, such as CVD, PVD, ALD, or any combination thereof, to fill the DSG holes.

Method 600 proceeds to operation 606, as illustrated in FIG. 6, in which all the second dielectric layers in the first region and parts of the second dielectric layers in the second region of the stack structure are replaced with conductive layers, for example, by a gate replacement process. The conductive layers can include a metal.

As illustrated in FIG. 5D, a slit 520 is an opening that extends vertically through stop layer 311, DSG layer 304, and first dielectric layers 203 and second dielectric layers 205 (a.k.a., stack sacrificial layers) of stack structure 201 until semiconductor layer 207. Slit 520 can also extend laterally across core array region 101 and connection region 103 in the x-direction (the word line direction), for example, corresponding to slit structure 108 in FIG. 1. In some implementations, fabrication processes for forming slit 520 include wet etching and/or dry etching, such as DRIE, of first dielectric layers 203 and second dielectric layers 205. The etching process through stack structure 201 may not stop at the top surface of semiconductor layer 207 and may continue to etch part of semiconductor layer 207 to ensure that slit 520 extends vertically all the way through all first dielectric layers 203 and second dielectric layers 205 of stack structure 201.

As illustrated in FIG. 5E, the part of slit 520 in core array region 101 is covered by a sacrificial layer 524. In some implementations, sacrificial layer 524 different from first dielectric layers 203 and second dielectric layers 205, such as a polysilicon layer or a carbon layer, is deposited into slit 520 using one or more thin film deposition processes, such as CVD, PVD, ALD, or any combination thereof, to at least partially fill slit 520 (covering the exposed first dielectric layers 203 and second dielectric layers 205 in slit 520). Sacrificial layer 524 can then be patterned using lithography and wet etching and/or dry etching to remove the part of sacrificial layer 524 in connection region 103, leaving only the part of sacrificial layer 524 in core array region 101 to cover only the part of slit 520 in core array region 101.

Parts of second dielectric layers 205 in conductive portion 105 of connection region 103 are removed by wet etching to form lateral recesses 526, leaving the remainders of second dielectric layers 205 in dielectric portion 107 of connection region 103 intact. In some implementations, the parts of second dielectric layers 205 are wet etched by applying a wet etchant through the part of slit 520 in connection region 103 that is uncovered by sacrificial layer 524, creating lateral recesses 526 interleaved between first dielectric layers 203. The wet etchant can include phosphoric acid for etching second dielectric layers 205 including silicon nitride. In some implementations, the etching rate and/or etching time are controlled to remove only the parts of second dielectric layers 205 in conductive portion 105, leaving the remainders of second dielectric layers 205 intact in dielectric portion 107. By controlling the etching time, the wet etchant does not travel all the way to completely remove second dielectric layers 205 in connection region 103, thereby defining two portions in connection region 103—dielectric portion 107 in which second dielectric layers 205 are removed, and dielectric portion 107 in which second dielectric layers 205 remain. As illustrated in FIG. 5E, since the part of slit 520 in core array region 101 is covered by sacrificial layer 524 that is resistant to the etchant for removing second dielectric layers 205, all second dielectric layers 205 remain intact in core array region 101.

As illustrated in FIG. 5F, the part of slit 520 in core array region 101 is re-opened by removing sacrificial layer 524 (shown in FIG. 5E) to expose first dielectric layers 203 and second dielectric layers 205. In some implementations, sacrificial layer 524 is selectively etched away from the part of slit 520 in core array region 101, for example, using potassium hydroxide (KOH) for etching sacrificial layer 524 having polysilicon to open the part of slit 520 in core array region 101.

Also, as illustrated in FIG. 5F, lateral recesses 526 (shown in FIG. 5E) and the part of slit 520 in connection region 103 are covered by a sacrificial layer 528. In some implementations, sacrificial layer 528 that is different from first dielectric layers 203 and second dielectric layers 205, such as a polysilicon layer or a carbon layer, is deposited into lateral recesses 526 and slit 520 using one or more thin film deposition processes, such as CVD, PVD, ALD, or any combination thereof, to at least partially fill slit 520 (covering the exposed first dielectric layers 203 and second dielectric layers 205). Sacrificial layer 528 can then be patterned using lithography and wet etching and/or dry etching to remove the part of sacrificial layer 528 in core array region 101, leaving only the part of sacrificial layer 528 in connection region 103 to cover only lateral recesses 526 and the part of slit 520 in connection region 103, but not in core array region 101. It is understood that lateral recesses 526 may be considered as parts of slit 520 in connection region 103. Thus, even if only lateral recesses 526 are fully or partially filled by sacrificial layer 528 (e.g., as shown in FIG. 5F), the part of slit 520 in connection region 103 may still be considered as being covered.

All second dielectric layers 205 in core array region 101 (as shown in FIG. 5E) are fully removed by wet etching to form lateral recesses 530. In some implementations, second dielectric layers 205 are wet etched by applying a wet etchant through the part of slit 520 in core array region 101 that is uncovered by sacrificial layer 528, creating lateral recesses 530 interleaved between first dielectric layers 203. The wet etchant can include phosphoric acid for etching second dielectric layers 205 including silicon nitride. In some implementations, the etching rate and/or etching time are controlled to ensure that all second dielectric layers 205 in core array region 101 are completely etched away. As illustrated in FIG. 5F, since the part of slit 520 in connection region 103 is covered by sacrificial layer 528 that is resistant to the etchant for removing second dielectric layers 205, the remainders of second dielectric layers 205 in dielectric portion 107 of connection region 103 remain intact.

As illustrated in FIG. 5G, the part of slit 520 in connection region 103 is re-opened by removing sacrificial layer 528 (shown in FIG. 5F) to expose first dielectric layers 203 and the remainder of second dielectric layers 205 in connection region 103. In some implementations, sacrificial layer 528 is selectively etched away from the part of slit 520 in connection region 103, for example, using KOH for etching sacrificial layer 528 having polysilicon, to open the part of slit 520 (and lateral recesses 526) in connection region 103.

As illustrated in FIG. 5H, conductive layers 275 are deposited into lateral recesses 530 and 526 (shown in FIG. 5G) in core array region 101 and conductive portion 105 of connection region 103 through slit 520. In some implementations, high-k gate dielectric layers 342 are deposited into lateral recesses 526 and 530 prior to conductive layers 275, such that conductive layers 275 are deposited on and surrounded by high-k gate dielectric layers 342. Conductive layers 275, such as metal layers, can be deposited using one or more thin film deposition processes, such as ALD, CVD, PVD, any other suitable processes, or any combination thereof.

As illustrated in FIG. 5I, a slit spacer 309 is formed in slit 520 (shown in FIG. 5H) to form slit structure 108 extending vertically through interleaved conductive layers 275 and first dielectric layers 203 of stack structure 201 and laterally across core array region 101 and conductive portion 105 of connection region 103. Slit spacer 309 can be formed by depositing dielectrics into slit 520 using one or more thin film deposition processes, such as ALD, CVD, PVD, any other suitable processes, or any combination thereof. In some implementations, conductive materials (e.g., as a source contact) are deposited into slit 520 after slit spacer 309 as part of slit structure 108.

Method 600 proceeds to operation 608, as illustrated in FIG. 6, in which contact structures extending through the first dielectric layers and remainders of the second dielectric layers in the second region of the stack structure are formed, such that the contact structures are connected to the conductive layers, respectively, in the second region of the stack structure.

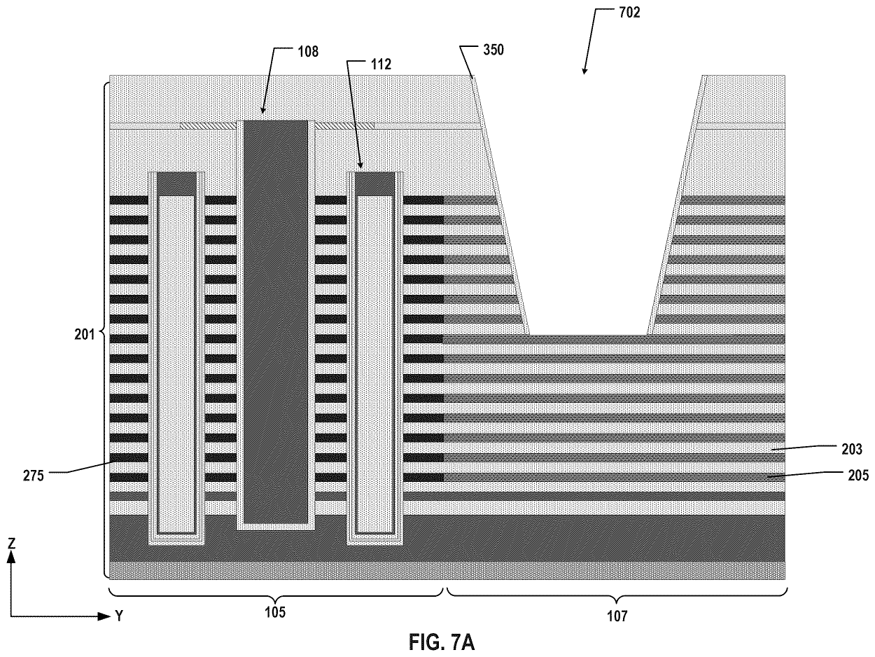

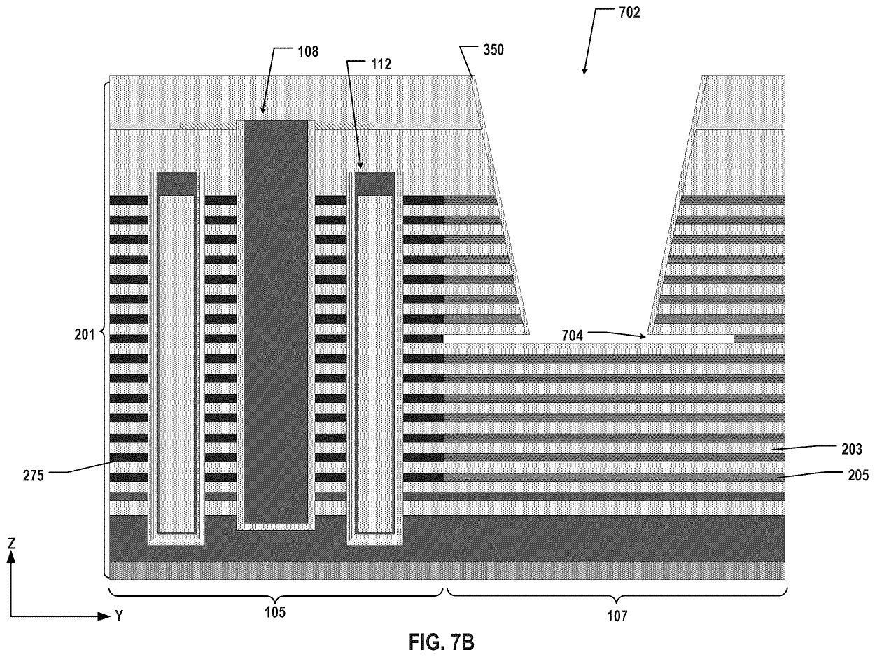

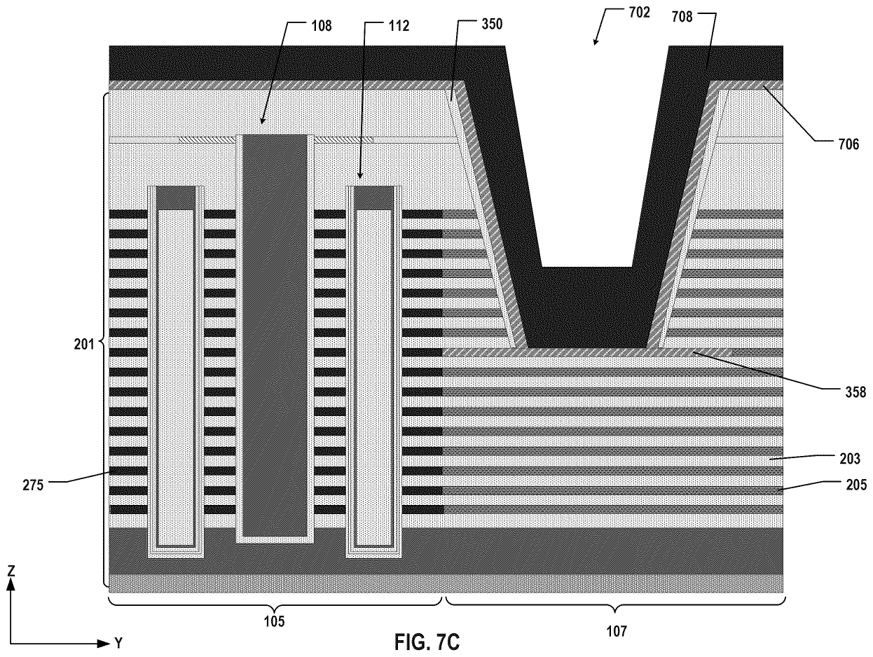

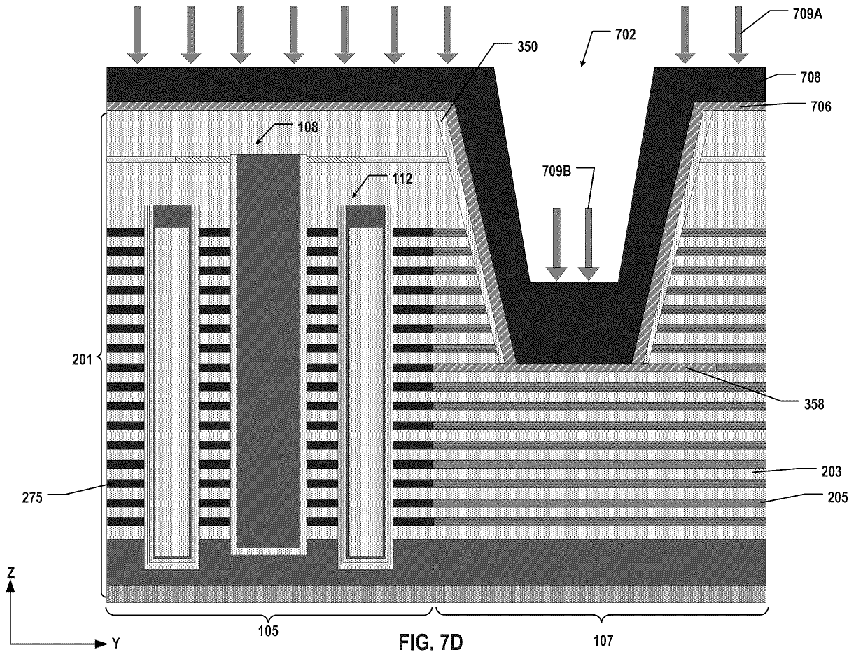

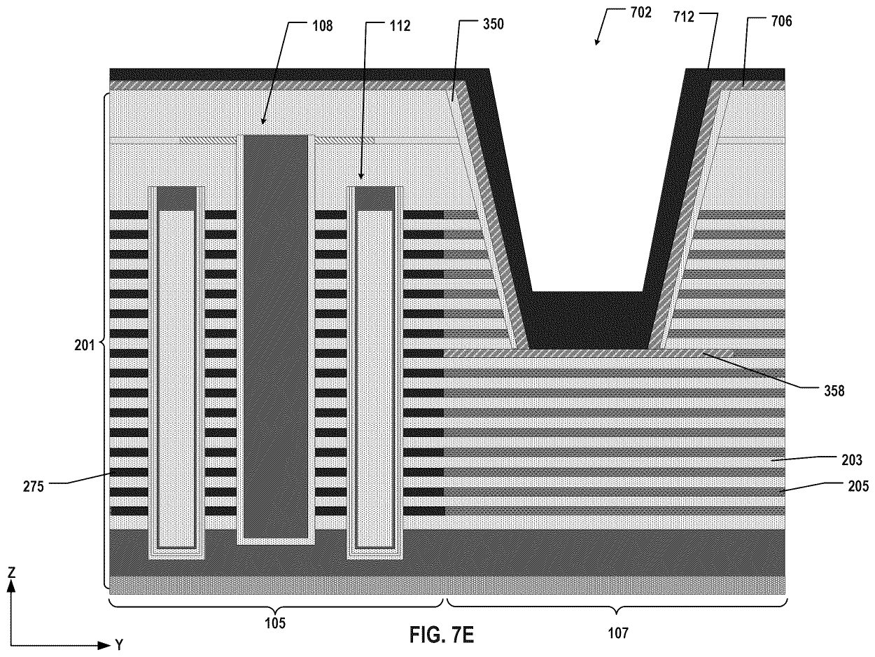

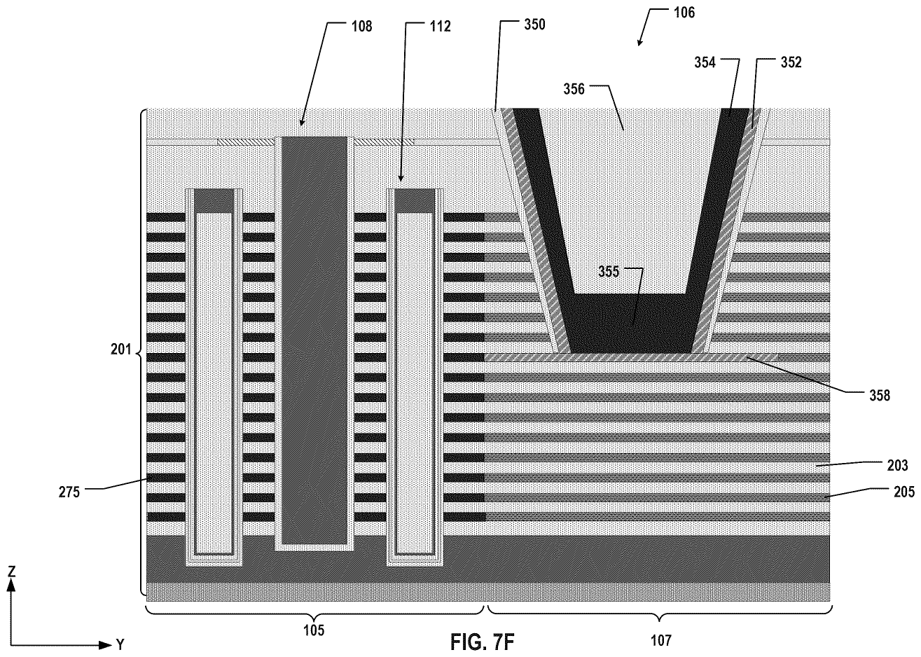

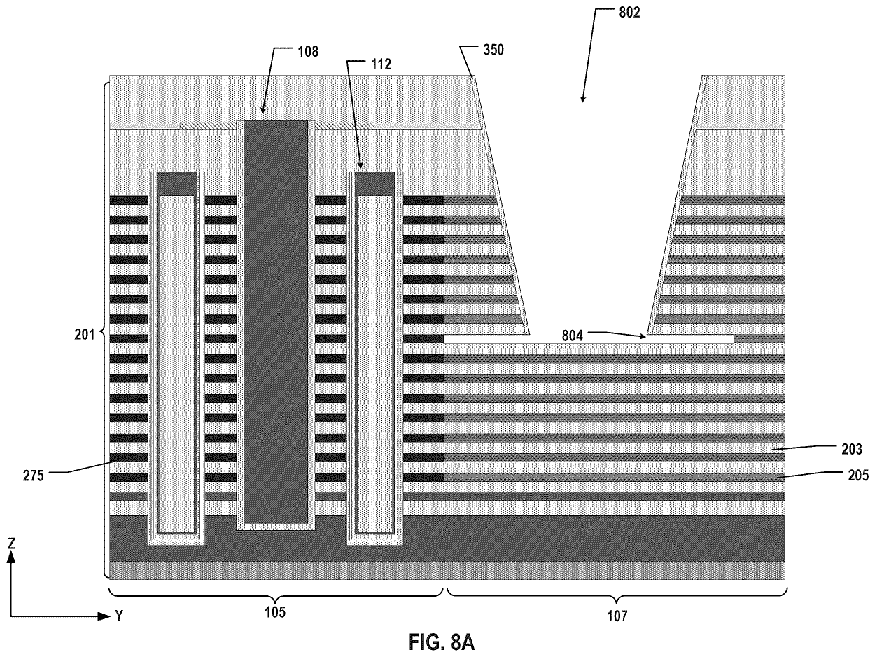

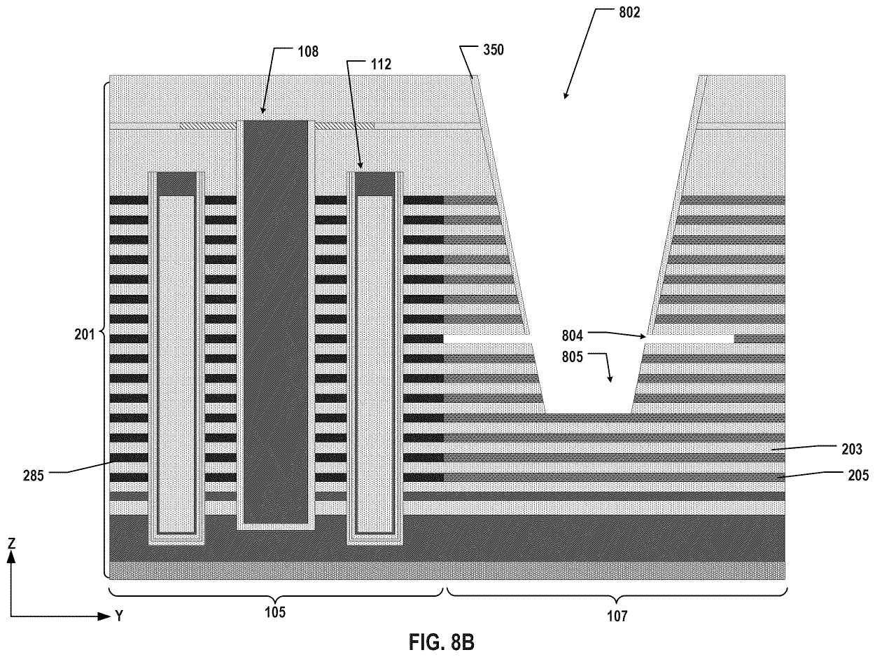

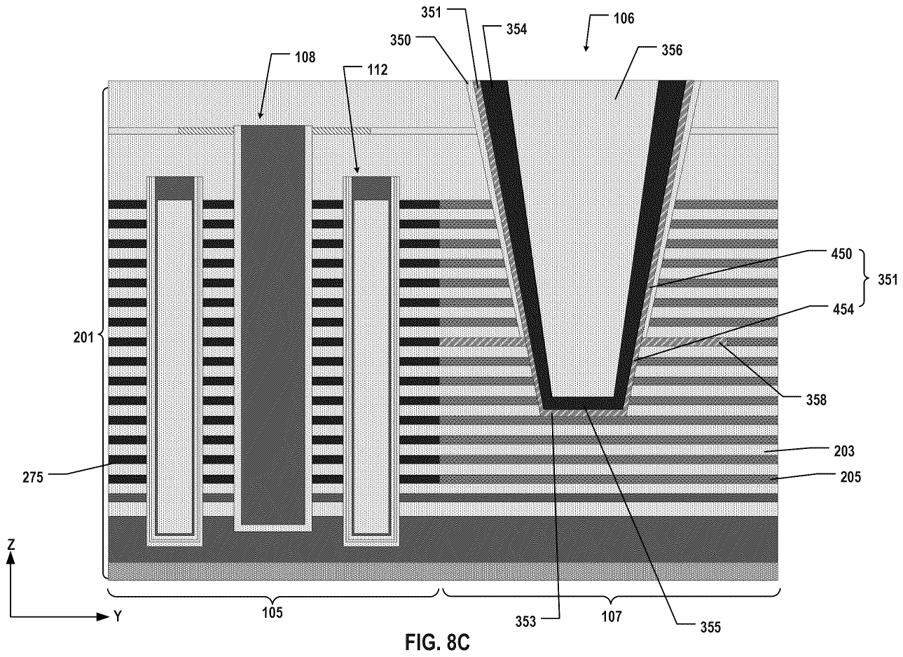

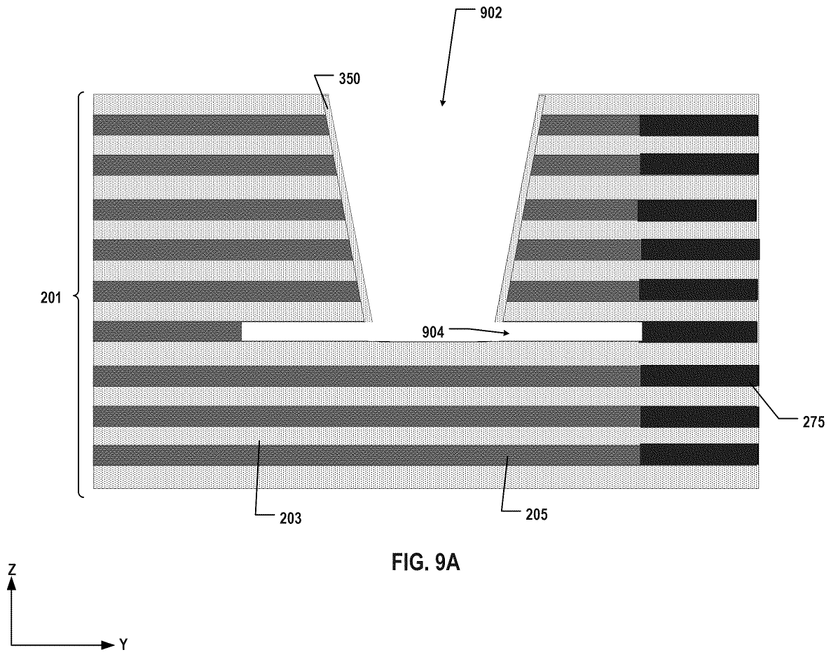

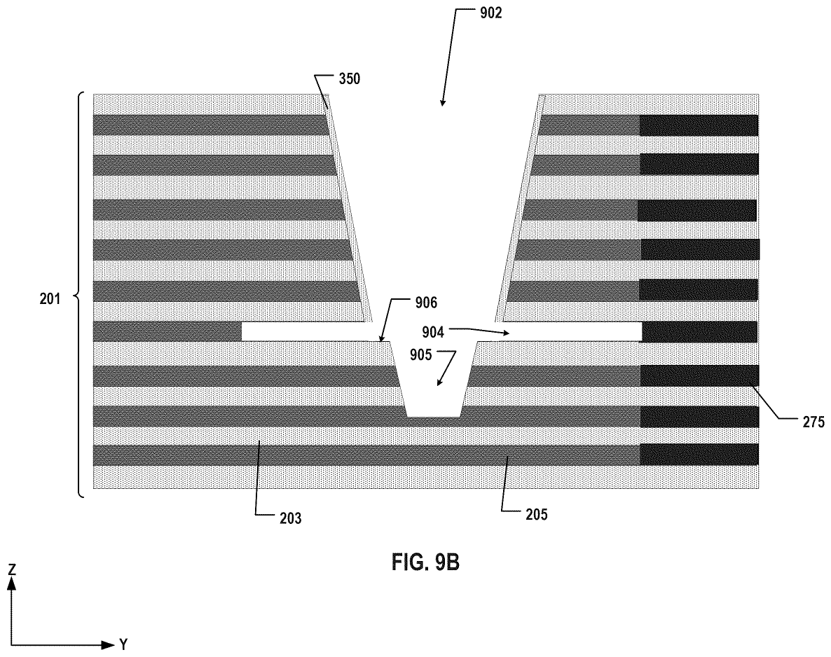

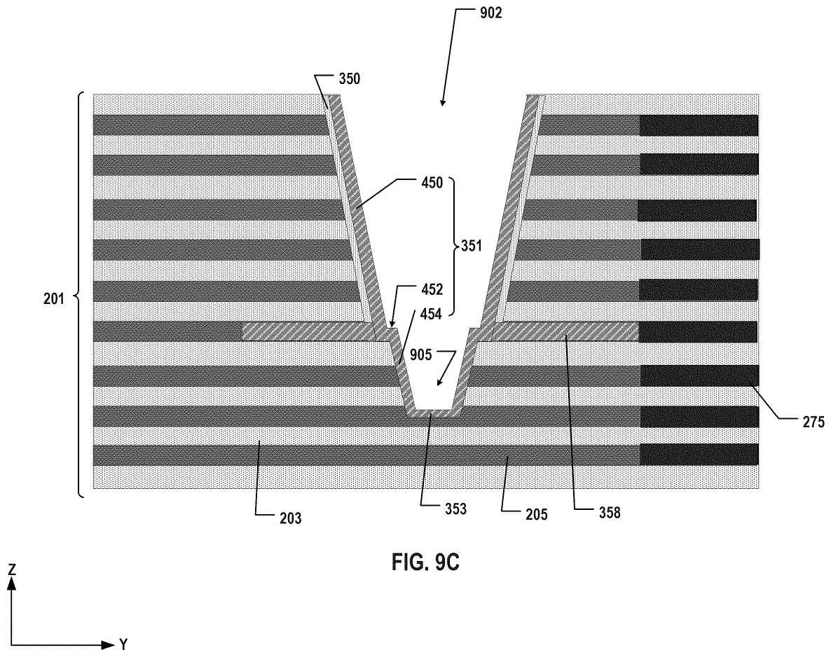

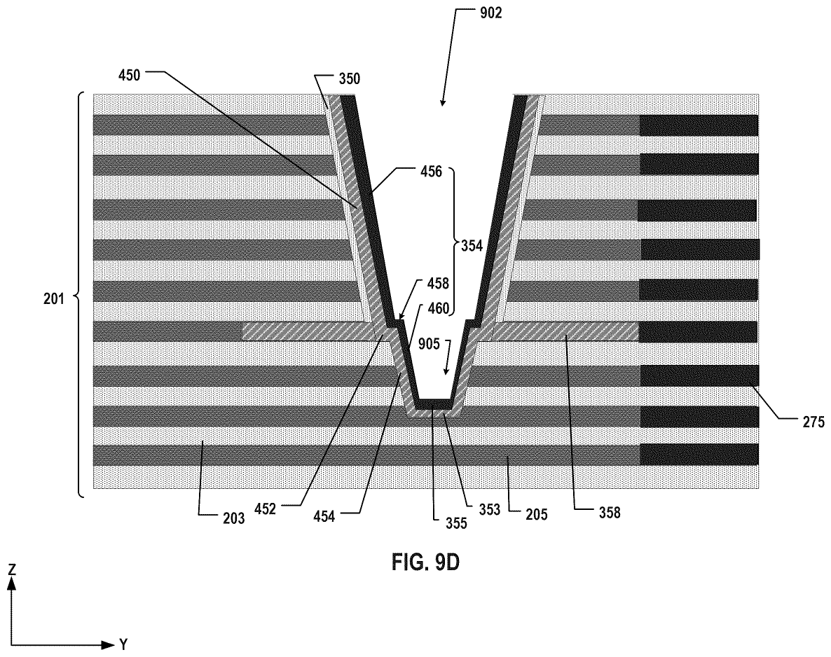

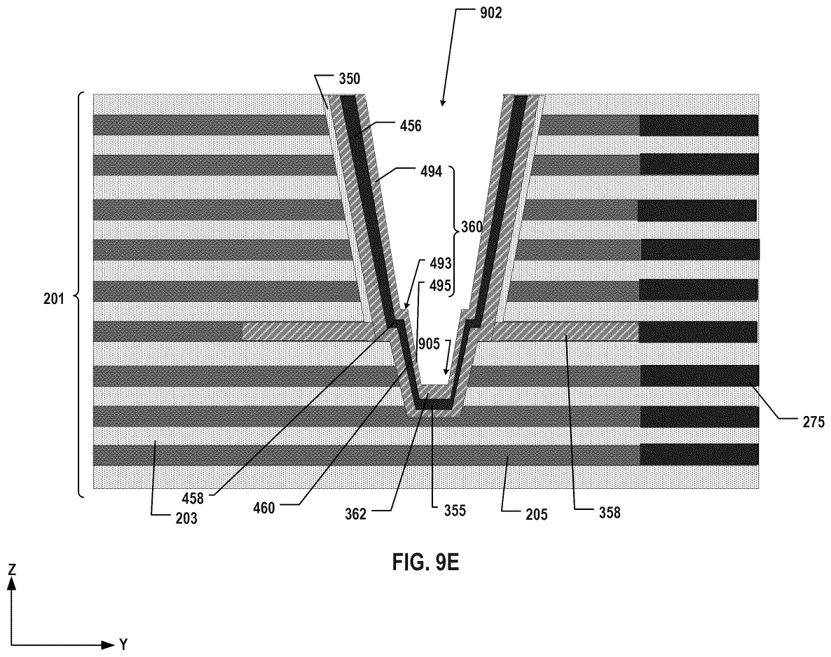

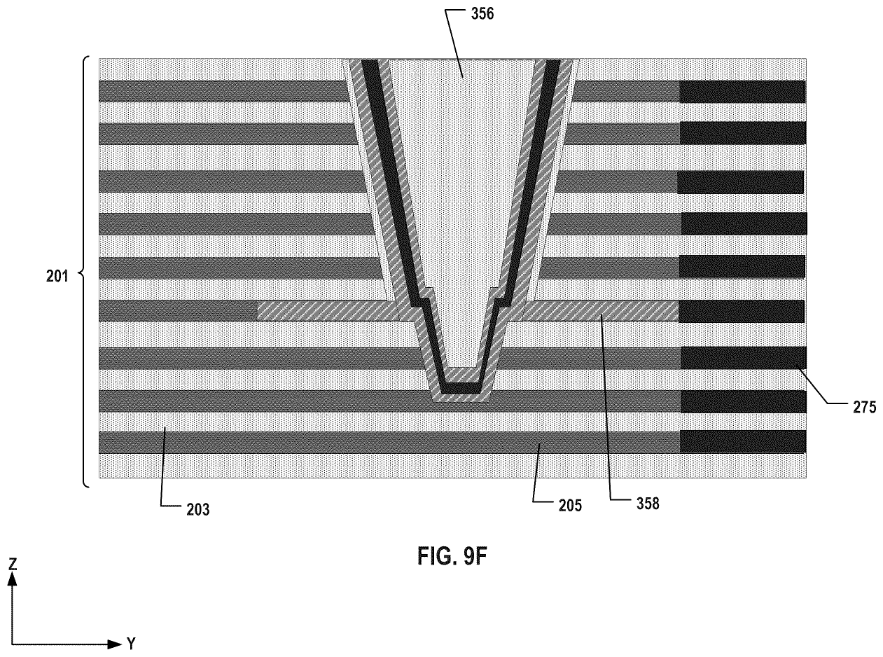

In some implementations, as illustrated in FIG. 5J, contact structures 106 are formed in dielectric portion 107 of connection region 103, by performing operations like those described below with reference to FIGS. 7A-7F. As a result, memory device 300 shown in FIG. 3A is formed. In some implementations, as illustrated in FIG. 5I, contact structures 106 are formed in dielectric portion 107 of connection region 103, by performing operations like those described below with reference to FIGS. 8A-8C. As a result, memory device 300 shown in FIG. 3B is formed. In some implementations, as illustrated in FIG. 9A-9F below, contact structures 106 including contact shoulders 458 are formed in dielectric portion 107 of connection region 103.

FIGS. 7A-7F illustrate a fabrication process for forming contact structures 106 in stack structure 201, according to some aspects of the present disclosure. As shown in FIG. 7A, stack structure 201 may be etched to form an opening 702. In some implementations, fabrication processes for forming opening 702 include wet etching and/or dry etching, such as deep-ion reactive etching (DRIE). In some implementations, opening 702 can be formed using a chopping process. As used herein, a “chopping” process is a process that increases the depth of one or more openings extending through interleaved first and second dielectric layers by a plurality of etching cycles. Each etch cycle can include one or more dry etch and/or wet etch processes that etch one pair of first and second dielectric layers, i.e., reducing the depth by a stack pair.

Contact spacer 350 is formed on a sidewall and a bottom surface of opening 702, thereby covering first dielectric layers 203 and second dielectric layers 205 exposed from the sidewall and bottom surface of opening 702. In some implementations, contact spacer 350 is formed by depositing dielectric materials, such as silicon oxide, using one or more thin film deposition processes, such as ALD, CVD, PVD, any other suitable processes, or any combination thereof, over the sidewall and the bottom surface of opening 702.

In some implementations, the part of contact spacer 350 on the bottom surface of opening 702 is removed, for example, by dry etching, to expose a part of second dielectric layer 205 in dielectric portion 107 of connection region 103. In some implementations, the etching rate, direction, and/or duration of DRIE are controlled to etch only the part of contact spacer 350 on the bottom surface, but not on the sidewall, of opening 702, i.e., “punching” through contact spacer 350 in the z-direction to expose only a corresponding second dielectric layer 205 from the bottom, but not other second dielectric layers 205 from the sidewall.

As illustrated in FIG. 7B, the part of second dielectric layer 205 exposed from the bottom of opening 702 is removed by wet etching to form a lateral opening 704, leaving the remainder of second dielectric layer 205 at the same level, as well as other second dielectric layers 205 at other levels, in dielectric portion 107 of connection region 103 intact. Lateral opening 704 can expose a corresponding conductive layer 275 at the same level in conductive portion 105 of connection region 103. In some implementations, the part of second dielectric layer 205 is wet etched by applying a wet etchant through opening 702, creating lateral opening 704 sandwiched between two first dielectric layers 203. The wet etchant can include phosphoric acid for etching second dielectric layer 205 including silicon nitride. In some implementations, the etching rate and/or etching time are controlled to remove only the part of second dielectric layer 205 that is enough to expose corresponding conductive layer 275 at the same level in conductive portion 105. By controlling the etching time, the wet etchant does not travel all the way to completely remove second dielectric layer 205 in dielectric portion 107. As a result, dummy channel structures 112 may not need to be formed in dielectric portion 107 of connection region 103 to provide mechanical support when removing second dielectric layer 205. As illustrated in FIG. 7B, since the sidewall of opening 702 is still covered by contact spacer 350 (e.g., silicon oxide) that is resistant to the etchant for removing second dielectric layers 205 (e.g., silicon nitride), second dielectric layers 205 at other levels remain intact in dielectric portion 107.

In some implementations in which high-k gate dielectric layers 342 are formed surrounding conductive layers 275, once the exposed part of second dielectric layer 205 is etched from opening 702, the corresponding high-k gate dielectric layer 342 surrounding the corresponding conductive layer 275 at the same level is exposed. The exposed part of the corresponding high-k gate dielectric layer 342 can then be etched, for example, using wet etching, to expose the corresponding conductive layer 275 at the same level.

As illustrated in FIG. 7C, third contact member 358 is formed by depositing a conductive layer through opening 702 to fill lateral opening 704. The conductive layer, such as a metal layer, can be deposited using one or more thin film deposition processes, such as ALD, CVD, PVD, any other suitable processes, or any combination thereof. The deposition rate and/or duration may be controlled to ensure that third contact member 358 can be in contact with the exposed corresponding conductive layer 275 at the same level as lateral opening 704. In other words, second dielectric layer 205 exposed from the bottom of opening 702 can be partially replaced with a corresponding third contact member 358 in dielectric portion 107 of connection region 103, while other second dielectric layers 205 at other levels in dielectric portion 107 remain intact.

A preliminary outer layer 706 is formed on the sidewall of contact spacer 350 and on top of stack structure 201 in connection region 103. Preliminary outer layer 706 is in contact with third contact member 358. Preliminary outer layer 706 can be formed in the same process as forming third contact member 358 by depositing the conductive layer (e.g., a TiN layer) not only into lateral opening 704, but also on the sidewall of contact spacer 350, using one or more thin film deposition processes, such as ALD, CVD, PVD, any other suitable processes, or any combination thereof. In this case, preliminary outer layer 706 and third contact member 358 may be formed with the same conductive material and the boundary between them is invisible.

A preliminary contact layer 708 is formed on the bottom of opening 702 and on top of preliminary outer layer 706 to cover preliminary outer layer 706 in connection region 103. Preliminary contact layer 708 can be formed by depositing another conductive layer (e.g., a W layer) on the bottom of opening 702 and on top of preliminary outer layer 706, using one or more thin film deposition processes, such as ALD, CVD, PVD, any other suitable processes, or any combination thereof.

As shown in FIG. 7D, a curing treatment may be performed on flat portions of preliminary contact layer 708 (but not the sidewall of preliminary contact layer 708), as shown by arrows 709A and 709B in FIG. 7D). With the curing treatment, an etching rate of the flat portions of preliminary contact layer 708 is slower than an etching rate of the sidewall of preliminary contact layer 708.

As shown in FIG. 7E, a part of preliminary contact layer 708 may be removed using dry etching and/or wet etching to form contact layer 712. Contact layer 712 may cover preliminary outer layer 706 and the bottom of opening 702. Because the etching rate of the flat portions of preliminary contact layer 708 is slower than the etching rate of the sidewall of preliminary contact layer 708, the thickness of the flat bottom portion of contact layer 712 in the z-direction is greater than the thickness of the sidewall of contact layer 712 in the y-direction. The flat bottom portion of contact layer 712 becomes second contact member 355.

As shown in FIG. 7F, a part of preliminary outer layer 706 that is outside opening 702 is removed to form outer metal layer 352. A part of contact layer 712 that is outside opening 702 is also removed, such that the remaining contact layer 712 formed on the sidewall of outer metal layer 352 and above second contact member 355 becomes first contact member 354. Filler 356 is formed in the remaining portion of opening 702 to fully or partially fill opening 702. Filler 356, such as a dielectric layer, can be deposited using one or more thin film deposition processes, such as ALD, CVD, PVD, any other suitable processes, or any combination thereof. The excess portions of the conductive layers and the dielectric layer for forming outer metal layer 352, first contact member 354, and filler 356 can be removed by using chemical mechanical polishing (CMP).

In some implementations, before forming filler 356 in the remaining portion of opening 702, first inner metal layer 360 and second inner metal layer 362 can be formed on a sidewall of first contact member 354 and on top of second contact member 355, respectively, in the same process by depositing a conductive layer (e.g., a TiN layer) using one or more thin film deposition processes, such as ALD, CVD, PVD, any other suitable processes, or any combination thereof. As a result, contact structure 106 shown in FIG. 4A can be formed.

FIGS. 8A-8C illustrate another fabrication process for forming contact structures 106 in stack structure 201, according to some aspects of the present disclosure. As shown in FIG. 8A, stack structure 201 may be etched to form an opening 802 extending in the z-direction and a lateral opening 804 below opening 802, by performing operations like those described above with reference to FIGS. 7A-7B. Contact spacer 350 may be formed on a sidewall of opening 802, by performing operations like those described above with reference to FIG. 7B.

Referring to FIG. 8B, stack structure 201 may be further etched to form an opening 805 below lateral opening 804. In some implementations, fabrication processes for forming opening 805 include wet etching and/or dry etching, such as DRIE. In some implementations, opening 805 can be formed using a chopping process.

Referring to FIG. 8C, contact structure 106 can be formed to extend into stack structure 201 in the z-direction. Specifically, third contact member 358 is formed in lateral opening 804. First outer metal layer 351 is formed on a sidewall of contact spacer 350 and a sidewall of opening 805. For example, first outer segment 450 of first outer metal layer 351 is formed on the sidewall of contact spacer 350. Second outer segment 454 of first outer metal layer 351 is formed on the sidewall of opening 805. Second outer metal layer 353 is formed on the bottom of opening 805 and connects to an end of second outer segment 454. First outer segment 450 and second outer segment 454 connect to third contact member 358, respectively. First outer metal layer 351 (including first outer segment 450 and second outer segment 454) and second outer metal layer 353 can be formed in the same process as forming third contact member 358 by depositing a conductive layer (e.g., a TiN layer) into lateral opening 804, on the sidewall of contact spacer 350, on the sidewall of opening 805, and on the bottom of opening 805, using one or more thin film deposition processes, such as ALD, CVD, PVD, any other suitable processes, or any combination thereof.

Next, second contact member 355 is formed on top of second outer metal layer 353, and first contact member 354 is formed on a sidewall of first outer metal layer 351 and above second contact member 355. First and second contact members 354 and 355 can be formed in the same process by depositing another conductive layer (e.g., a W layer) on the sidewall of first outer metal layer 351 and on top of second outer metal layer 353, using one or more thin film deposition processes, such as ALD, CVD, PVD, any other suitable processes, or any combination thereof.

Filler 356 is formed in the remaining portion of openings 802 and 805 to fully or partially fill the openings. Filler 356, such as a dielectric layer, can be deposited using one or more thin film deposition processes, such as ALD, CVD, PVD, any other suitable processes, or any combination thereof. As a result, contact structure 106 shown in FIG. 3B is formed.

In some implementations, before the formation of filler 356, first inner metal layer 360 and second inner metal layer 362 can be formed on a sidewall of first contact member 354 and on top of second contact member 355, respectively, in the same process by depositing a conductive layer (e.g., a TiN layer) using one or more thin film deposition processes, such as ALD, CVD, PVD, any other suitable processes, or any combination thereof. Then, filler 356 is formed in the remaining portion of openings 802 and 805 to fully or partially fill the openings. As a result, contact structure 106 shown in FIG. 4C is formed.

FIGS. 9A-9F illustrate still another fabrication process for forming contact structures 106 in stack structure 201, according to some aspects of the present disclosure. As shown in FIG. 9A, stack structure 201 may be etched to form an opening 902 extending in the z-direction and a lateral opening 904 below opening 902, by performing operations like those described above with reference to FIGS. 7A-7B. Contact spacer 350 may be formed on a sidewall of opening 902, by performing operations like those described above with reference to FIG. 7B.

Referring to FIG. 9B, stack structure 201 may be further etched to form an opening 905 below lateral opening 904. A sidewall shoulder 906 is formed in a region where lateral opening 904 meets opening 905. In some implementations, fabrication processes for forming opening 905 include wet etching and/or dry etching, such as DRIE. In some implementations, opening 905 can be formed using a chopping process.

Referring to FIG. 9C, third contact member 358 is formed in lateral opening 904. First outer metal layer 351 is formed on a sidewall of contact spacer 350, on sidewall shoulder 906, and on a sidewall of opening 905. For example, first outer segment 450 of first outer metal layer 351 is formed on the sidewall of contact spacer 350. Outer metal shoulder 452 of first outer metal layer 351 is formed on sidewall shoulder 906. Second outer segment 454 of first outer metal layer 351 is formed on the sidewall of opening 905. Second outer metal layer 353 is formed on the bottom of opening 905 and connects to an end of second outer segment 454. Outer metal shoulder 452 connects to third contact member 358. First outer metal layer 351 (including first outer segment 450, outer metal shoulder 452, and second outer segment 454) and second outer metal layer 353 can be formed in the same process as forming third contact member 358 by depositing a conductive layer (e.g., a TiN layer) into lateral opening 904, on the sidewall of contact spacer 350, on sidewall shoulder 906, on the sidewall of opening 905, and on the bottom of opening 905, using one or more thin film deposition processes, such as ALD, CVD, PVD, any other suitable processes, or any combination thereof.

Referring FIG. 9D, second contact member 355 is formed on top of second outer metal layer 353, and first contact member 354 is formed on a sidewall of first outer metal layer 351 and above second contact member 355. For example, a first contact segment 456 of first contact member 354 is formed on a sidewall of first outer segment 450. Contact shoulder 458 of first contact member 354 is formed on outer metal shoulder 452. Second contact segment 460 of first contact member 354 is formed on a sidewall of second outer segment 454. First and second contact members 354 and 355 can be formed in the same process by depositing another conductive layer (e.g., a W layer) on the sidewall of first outer metal layer 351 and on top of second outer metal layer 353, using one or more thin film deposition processes, such as ALD, CVD, PVD, any other suitable processes, or any combination thereof.

Referring to FIG. 9E, first inner metal layer 360 and second inner metal layer 362 can be formed on a sidewall of first contact member 354 and on top of second contact member 355, respectively. For example, a first inner segment 494 of first inner metal layer 360 is formed on a sidewall of first contact segment 456; inner metal shoulder 493 of first inner metal layer 360 is formed on contact shoulder 458; and a second inner segment 495 of first inner metal layer 360 is formed on a sidewall of second contact segment 460. First inner metal layer 360 and second inner metal layer 362 can be formed in the same process by depositing a conductive layer (e.g., a TiN layer) on the sidewall of first contact member 354 and on top of second contact member 355, respectively, using one or more thin film deposition processes, such as ALD, CVD, PVD, any other suitable processes, or any combination thereof.

Referring to FIG. 9F, filler 356 is formed in the remaining portion of openings 902 and 905 to fully or partially fill the openings. Filler 356, such as a dielectric layer, can be deposited using one or more thin film deposition processes, such as ALD, CVD, PVD, any other suitable processes, or any combination thereof.

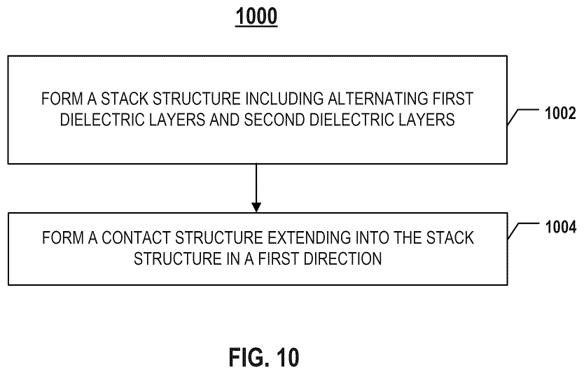

FIG. 10 is a flowchart of another method 1000 for forming a 3D memory device having contact structures, according to some aspects of the present disclosure. The 3D memory device can be memory device 100 or 300, or any other memory device disclosed herein. It is understood that the operations shown in method 1000 are not exhaustive and that other operations can be performed as well before, after, or between any of the illustrated operations. Further, some of the operations may be performed simultaneously, or in a different order than shown in FIG. 10.

Referring to FIG. 10, method 1000 starts at operation 1002, in which a stack structure is formed over a semiconductor layer. The stack structure includes alternating first dielectric layers and second dielectric layers. For example, stack structure 201 can be formed by performing operations like those described above with reference to FIG. 5A.

Method 1000 proceeds to operation 1004, as illustrated in FIG. 10, in which a contact structure extending into the stack structure in a first direction is formed. The contact structure may include a first contact member extending in the first direction, a second contact member connecting to a first end of the first contact member and extending in a second direction intersected with the first direction, and a third contact member extending in the second direction and connecting to the first contact member. The third contact member is located between the first end and a second end of the first contact member. For example, contact structure 106 may be formed by performing operations like those described above with reference to FIGS. 8A-8C or FIGS. 9A-9F, and the similar description will not be repeated herein.

In some implementations, forming the contact structure includes forming a contact hole extending into the stack structure in the first direction; and forming the contact structure in the contact hole. Specifically, forming the contact hole includes: forming a first opening extending into the stack structure in the first direction; forming a lateral opening below a bottom of the first opening; and forming a second opening below a bottom of the lateral opening. The second opening extends further into the stack structure from the bottom of the lateral opening in the first direction. For example, with reference to FIGS. 8A and 8B, the contact hole may include opening 802, lateral opening 804, and opening 805, and operations described above with reference to FIGS. 8A-8B can be performed to form the contact hole. In another example, with reference to FIGS. 9A-9B, the contact hole may include opening 902, lateral opening 904, and opening 905, and operations described above with reference to FIGS. 9A-9B can be performed to form the contact hole.

In some implementations, forming the contact structure further includes forming the third contact member in the lateral opening; forming a first outer metal layer on a sidewall of the contact hole; and forming a second outer metal layer on a bottom of the second opening. The second outer metal layer connects to a first end of the first outer metal layer, and the third contact member connects to the first outer metal layer between the first end and a second end of the first outer metal layer. For example, third contact member 358, first outer metal layer 351, and second outer metal layer 353 can be formed by performing operations like those described above with reference to FIG. 8C or FIG. 9C.

In some implementations, forming the contact structure further includes forming the second contact member on the second outer metal layer; and forming the first contact member on a sidewall of the first outer metal layer. For example, first contact member 354 and second contact member 355 can be formed by performing operations like those described above with reference to FIG. 8C or FIG. 9D.

In some implementations, forming the contact structure further includes forming a contact spacer on a sidewall of the first opening before the lateral opening is formed below the bottom of the first opening. For examples, contact spacer 350 can be formed by performing operations like those described above with reference to FIG. 8A or FIG. 9A. Forming the first outer metal layer on the sidewall of the contact hole includes forming a first outer segment of the first outer metal layer on a sidewall of the contact spacer, where the first outer segment is located on a first side of the third contact member that is away from the second contact member; and forming a second outer segment of the first outer metal layer on a sidewall of the second opening, where the second outer segment is located on a second side of the third contact member that is close to the second contact member and opposite to the first side. For example, first outer segment 450 and second outer segment 454 can be formed by performing operations like those described above with reference to FIG. 8C or FIG. 9C.

In some implementations, a sidewall shoulder is formed in a region where the lateral opening meets the second opening. Forming the first outer metal layer on the sidewall of the contact hole further includes forming an outer metal shoulder of the first outer metal layer on the sidewall shoulder, where the outer metal shoulder connects to the third contact member. For example, outer metal shoulder 452 can be formed by performing operations like those described above with reference to FIG. 9C. Forming the first contact member on the sidewall of the first outer metal layer includes forming a first contact segment on a sidewall of the first outer segment, a contact shoulder on the outer metal shoulder, and a second contact segment on a sidewall of the second outer segment. The contact shoulder connects to the first contact segment and the second contact segment. The contact shoulder also connects to the outer metal shoulder. For example, contact shoulder 458 can be formed on outer metal shoulder 452 by performing operations like those described above with reference to FIG. 9D.

In some implementations, forming the contact structure further includes forming a first inner metal layer on a sidewall of the first contact member; and forming a second inner metal layer on the second contact member. The second inner metal layer connects to an end of the first inner metal layer. For example, first inner metal layer 360 and second inner metal layer 362 can be formed by performing operations like those described above with reference to FIG. 9E.

In some implementations, the stack structure includes a first portion and a second portion adjacent to the first portion, and the contact structure extends in the first portion of the stack structure. Method 1000 further includes performing a gate line replacement process to replace parts of the second dielectric layers in the second portion of the stack structure with conductive layers. The third contact member is in the same layer as one of conductive layers and connects to the one of the conductive layers. For example, the gate line replacement process may be performed by performing operations like those described above with reference to FIGS. 5D-5H.

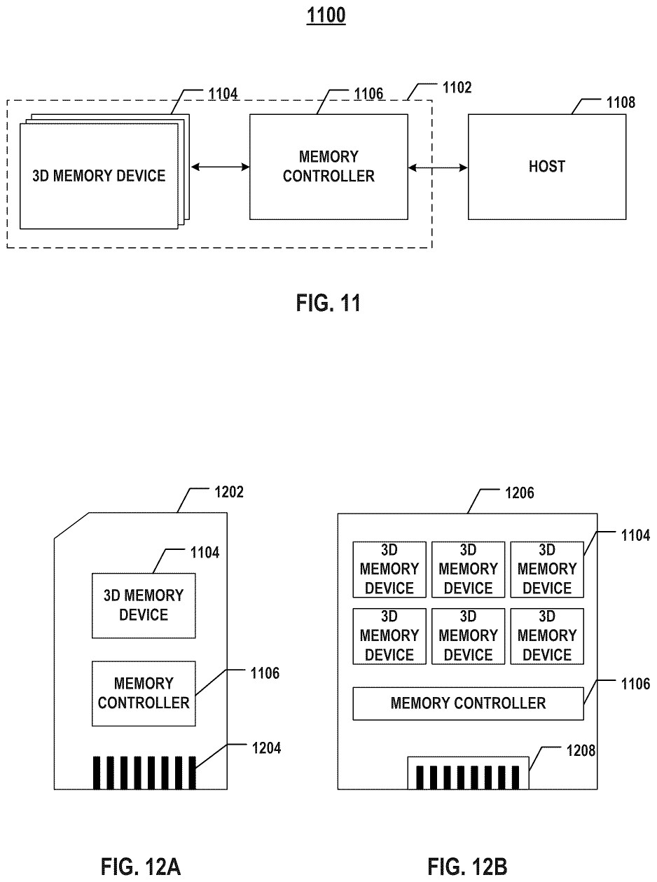

FIG. 11 illustrates a block diagram of an exemplary system 1100 having a 3D memory device, according to some aspects of the present disclosure. System 1100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 11, system 1100 can include a host 1108 and a memory system 1102 having one or more 3D memory devices 1104 and a memory controller 1106. Host 1108 can be a processor of an electronic device, such as a central processing unit (CPU), or a system-on-chip (SoC), such as an application processor (AP). Host 1108 can be configured to send or receive data to or from 3D memory devices 1104.

3D memory device 1104 can be any 3D memory device disclosed herein, such as 3D memory device 100 in FIG. 1 and memory device 300 in FIG. 3A or 3B. In some implementations, each 3D memory device 1104 includes a NAND Flash memory. Consistent with the scope of the present disclosure, contact structures can replace the staircase structures and contacts to achieve word line pick-up/fan-out functions, thereby reducing the manufacturing cost and simplifying the fabrication process.

Memory controller 1106 (a.k.a., a controller circuit) is coupled to 3D memory device 1104 and host 1108 and is configured to control 3D memory device 1104, according to some implementations. For example, memory controller 1106 may be configured to operate the plurality of channel structures via the word lines. Memory controller 1106 can manage the data stored in 3D memory device 1104 and communicate with host 1108. In some implementations, memory controller 1106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1106 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1106 can be configured to control operations of 3D memory device 1104, such as read, erase, and program operations. Memory controller 1106 can also be configured to manage various functions with respect to the data stored or to be stored in 3D memory device 1104 including, but not limited to bad-block management, garbage collection, logical-to-physical address conversion, wear leveling, etc. In some implementations, memory controller 1106 is further configured to process error correction codes (ECCs) with respect to the data read from or written to 3D memory device 1104. Any other suitable functions may be performed by memory controller 1106 as well, for example, formatting 3D memory device 1104. Memory controller 1106 can communicate with an external device (e.g., host 1108) according to a particular communication protocol. For example, memory controller 1106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 1106 and one or more 3D memory devices 1104 can be integrated into various types of storage devices, for example, be included in the same package, such as a universal Flash storage (UFS) package or an eMMC package. That is, memory system 1102 can be implemented and packaged into different types of end electronic products. In one example as shown in FIG. 12A, memory controller 1106 and a single 3D memory device 1104 may be integrated into a memory card 1202. Memory card 1202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1202 can further include a memory card connector 1204 electrically coupling memory card 1202 with a host (e.g., host 1108 in FIG. 11). In another example as shown in FIG. 12B, memory controller 1106 and multiple 3D memory devices 1104 may be integrated into an SSD 1206. SSD 1206 can further include an SSD connector 1208 electrically coupling SSD 1206 with a host (e.g., host 1108 in FIG. 11). In some implementations, the storage capacity and/or the operation speed of SSD 1206 is greater than those of memory card 1202.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A memory device, comprising:
a stack structure comprising alternating first layers and first dielectric layers; and
a contact structure extending into the stack structure in a first direction and comprising:
a first contact member extending in the first direction, the first contact member comprising a first end and a second end which are oppositely disposed along the first direction;
a second contact member connecting to the first end of the first contact member and extending in a second direction intersected with the first direction; and
a third contact member extending in the second direction and connecting to the first contact member, wherein the third contact member is located between the first end of the first contact member and the second end of the first contact member.

2. The memory device of claim 1, wherein the first layers in a first portion of the stack structure comprise second dielectric layers, the contact structure extends into the first portion of the stack structure, and the third contact member and the second contact member are spaced apart by one or more layers from the first and second dielectric layers in the first direction.

3. The memory device of claim 1, wherein the contact structure further comprises:
a first outer metal layer extending in the first direction and surrounding the first contact member, the first outer metal layer comprising a first end and a second end which are oppositely disposed along the first direction; and
a second outer metal layer extending in the second direction, connecting to the first end of the first outer metal layer, and covering an outer surface of the second contact member,
wherein the third contact member connects to the first outer metal layer between the first end of the first outer metal layer and the second end of the first outer metal layer.

4. The memory device of claim 3, wherein:
the first outer metal layer comprises a first outer segment and a second outer segment;
the first outer segment is located on a first side of the third contact member that is away from the second contact member;
the second outer segment is located on a second side of the third contact member that is close to the second contact member and opposite to the first side; and
the contact structure further comprises a contact spacer extending in the first direction and surrounding the first outer segment.

5. The memory device of claim 1, wherein the contact structure further comprises:
a first inner metal layer extending in the first direction and surrounded by the first contact member; and
a second inner metal layer extending in the second direction, connecting to an end of the first inner metal layer, and covering an inner surface of the second contact member.

6. The memory device of claim 1, wherein the first contact member comprises:
a first contact segment, a contact shoulder, and a second contact segment, wherein the contact shoulder connects to the first contact segment and the second contact segment,
wherein the first contact segment is located on a first side of the third contact member that is away from the second contact member, and
wherein the second contact segment connects to the second contact member and is located on a second side of the third contact member that is opposite to the first side.

7. The memory device of claim 6, wherein in a second direction perpendicular to the first direction, a size of an end of the first contact segment that connects to the contact shoulder is greater than a size of an end of the second contact segment that also connects to the contact shoulder.

8. The memory device of claim 2, wherein:
the first layers in a second portion adjacent to the first portion of the stack structure comprise conductive layers; and
the third contact member is in a same layer as one of the conductive layers and connects to the one of the conductive layers.

9. A memory device, comprising:
a stack structure comprising alternating first layers and first dielectric layers; and
a contact structure extending into the stack structure in a first direction and comprising:
a first contact member extending in the first direction;
a second contact member connecting to an end of the first contact member and extending in a second direction intersected with the first direction; and
a third contact member extending in the second direction and connecting to the second contact member,
wherein a first thickness of the second contact member in the first direction is greater than a second thickness of the first contact member in the second direction.

10. The memory device of claim 9, wherein the second thickness of the first contact member is a maximal thickness of the first contact member in the second direction.

11. The memory device of claim 9, wherein the contact structure further comprises:
an outer metal layer extending in the first direction and surrounding the first contact member.

12. The memory device of claim 11, wherein the contact structure further comprises a contact spacer extending in the first direction and surrounding the outer metal layer.

13. A method for forming a memory device, comprising:
forming a stack structure comprising alternating first dielectric layers and second dielectric layers; and
forming a contact structure extending into the stack structure in a first direction, wherein the contact structure comprises:
a first contact member extending in the first direction, the first contact member comprising a first end and a second end which are oppositely disposed along the first direction;
a second contact member connecting to the first end of the first contact member and extending in a second direction intersected with the first direction; and
a third contact member extending in the second direction and connecting to the first contact member, wherein the third contact member is located between the first end of the first contact member and the second end of the first contact member.

14. The method of claim 13, wherein forming the contact structure comprises:
forming a contact hole extending into the stack structure in the first direction; and
forming the contact structure in the contact hole.

15. The method of claim 14, wherein forming the contact hole comprises:
forming a first opening extending into the stack structure in the first direction;
forming a lateral opening below a bottom of the first opening; and
forming a second opening below a bottom of the lateral opening, wherein the second opening extends further into the stack structure from the bottom of the lateral opening in the first direction.

16. The method of claim 15, wherein forming the contact structure further comprises:
forming the third contact member in the lateral opening;
forming a first outer metal layer on a sidewall of the contact hole; and
forming a second outer metal layer on a bottom of the second opening,
wherein the second outer metal layer connects to a first end of the first outer metal layer, and the third contact member connects to the first outer metal layer between the first end and a second end of the first outer metal layer.

17. The method of claim 16, wherein forming the contact structure further comprises:
forming the second contact member on the second outer metal layer; and
forming the first contact member on a sidewall of the first outer metal layer.

18. The method of claim 17, wherein:
forming the contact structure further comprises forming a contact spacer on a sidewall of the first opening before the lateral opening is formed below the bottom of the first opening; and
forming the first outer metal layer on the sidewall of the contact hole comprises:
forming a first outer segment of the first outer metal layer on a sidewall of the contact spacer, wherein the first outer segment is located on a first side of the third contact member that is away from the second contact member; and
forming a second outer segment of the first outer metal layer on a sidewall of the second opening, wherein the second outer segment is located on a second side of the third contact member that is close to the second contact member and opposite to the first side.

19. The method of claim 18, wherein:
a sidewall shoulder is formed in a region where the lateral opening meets the second opening;
forming the first outer metal layer on the sidewall of the contact hole further comprises forming an outer metal shoulder of the first outer metal layer on the sidewall shoulder, wherein the outer metal shoulder connects to the third contact member; and
forming the first contact member on the sidewall of the first outer metal layer comprises:
forming a first contact segment on a sidewall of the first outer segment, a contact shoulder on the outer metal shoulder, and a second contact segment on a sidewall of the second outer segment,
wherein the contact shoulder connects to the first contact segment and the second contact segment, and
wherein the contact shoulder also connects to the outer metal shoulder.

20. The method of claim 13, wherein forming the contact structure further comprises:
forming a first inner metal layer on a sidewall of the first contact member; and
forming a second inner metal layer on the second contact member, wherein the second inner metal layer connects to an end of the first inner metal layer.
